(19) United States
(12) Patent Application Publication
(10) Pub. No.: US 2026/0180339 A1
(43) Pub. Date: Jun. 25, 2026

(54) DETERMINING A VALUE OF A CHARACTERISTIC OF AN ELECTRIC POWER GRID

(71) Applicant: Reactive Technologies Limited, Oxford (GB)

(72) Inventors: Arpan KOIRALA, Helsinki (FN); Sung Pil OE, London (GB); Daniel GHEORGHE, Glasgow (GB)

(21) Appl. No.: 19/421,966

(22) Filed: Dec. 16, 2025

(30) Foreign Application Priority Data
Dec. 20, 2024 (GB) 2418908.6

(51) Int. Cl. H02J 3/48; G01R 31/08; H02J 3/001; H02J 3/18; H02J 13/12

(52) U.S. Cl. CPC H02J 3/48; G01R 31/086; H02J 3/00125; H02J 3/18; H02J 13/12

(57) ABSTRACT

A method for determining a first value of a characteristic of an electric power grid as observed at a first location of the electric power grid is disclosed. The method comprises obtaining a plurality of second values. Each second value is indicative of a relationship between a difference in measured voltage of the electric power grid at the first location before and after a respective power change and a difference in measured current of the electric power grid at the first location before and after the respective power change. Each power change causes an electric power flow in the electric power grid at the first location with a respective different ratio of reactive to active power. The method comprises determining, based on the plurality of second values, a third value indicative of an extremum of the relationship, and determining the first value based on the third value.

### CROSS-REFERENCE TO RELATED APPLICATIONS

This application claims priority to GB Application No. 2418908.6, filed Dec. 20, 2024, under 35 U.S.C. § 119 (a). The above-referenced patent application is incorporated by reference in its entirety.

### TECHNICAL FIELD

The present invention relates to a method, apparatus and system for determining a first value of a characteristic of an electric power grid as observed at a first location of the electric power grid.

### BACKGROUND

An electricity distribution network or electric power grid distributes electric power from generators or providers of electrical power to consumers of electrical power. A grid operator is tasked with maintaining proper operation of an electric power grid. To this end, it is useful for grid operators to determine or otherwise be provided with values of one or more characteristics of the grid. These can provide an insight to the state of operation of the grid and can accordingly be used to inform repair or optimisation of the configuration and/or operation of the grid, as needed, for example. Electric power grids typically comprise a transmission grid and a distribution grid and operate using AC voltage at a nominal grid frequency that is uniform throughout a synchronous area of the grid.

An AC system typically comprises both resistive components and reactive components. Resistive components cause power to be dissipated and/or consumed in-phase with the grid voltage. Reactive components cause power to be dissipated and/or consumed out of phase with the grid voltage. Accordingly, the electrical power flowing at a particular location in an AC circuit has an associated ratio of reactive to active power. The electrical power in an AC circuit is typically represented as the apparent power, a combined form of active power and reactive power. Impedance is a measure of the opposition to the flow of alternating current in a system. The complex-valued impedance is defined as:

$$Z = R + j X \qquad ( 1 )$$

where R is the resistance, and X is the reactance. Reactance may be caused by either inductive components and/or capacitive components. Examples of inductive components include overhead transmission lines and transformers. The magnitude of the impedance is defined as:

$$\vert Z \vert = \sqrt{{R}^{2} + {X}^{2}} \qquad ( 2 )$$

The impedance is useful in determining the system strength of a power grid, among other applications. An X/R ratio is the measure of the ratio of reactance to resistance as observed at a particular location in the grid. The impedance and/or X/R ratio of an electric power grid as observed at a particular location is useful information, for example in planning and/or maintaining proper operation of the electric power grid.

Traditionally, transmission grids are dominated by overhead power lines. Hence, the impedance of the grid is dominated by inductive reactance. Accordingly, traditionally, the impedance of the grid is approximated to the reactance of the grid, and the resistance of the grid is neglected. However, increasingly, power grids include inverters, underground cables and/or series capacitors. The X/R ratio of power grids, such as transmission grids, including inverters, underground cables and/or series capacitors may be low compared to power grids dominated by overhead power lines. In such cases, it may no longer be a good assumption to neglect the resistance, and hence the impedance may be inaccurately estimated.

It is known to estimate the X/R ratio using computer models and typically treat the X/R ratio as a constant parameter of the grid. However, these estimates may be inaccurate and do not account for any changes in the X/R ratio that might occur over time. Hence, it is difficult to determine an accurate X/R ratio and/or impedance of the grid, particularly in grids, such as transmissions grids, with a low X/R ratio. It is an object of the present invention to mitigate at least some of the drawbacks of the prior art.

### SUMMARY

According to a first aspect of the present invention, there is provided a method of determining a first value of a characteristic of an electric power grid as observed at a first location of the electric power grid, the method comprising: obtaining a plurality of second values, each second value being indicative of a relationship between a difference in measured voltage of the electric power grid at the first location before and after a respective power change and a difference in measured current of the electric power grid at the first location before and after the respective power change, each power change causing an electric power flow in the electric power grid at the first location with a respective different ratio of reactive to active power; determining, based on the plurality of second values, a third value indicative of an extremum of the relationship; and determining the first value based on the third value.

Optionally, each second value is indicative of a ratio of the difference in measured voltage of the electric power grid at the first location before and after the respective power change to the difference in measured current of the electric power grid at the first location before and after the respective power change.

Optionally, the third value is indicative of a maximum of the ratio.

Optionally, each second value is indicative of a measured impedance of the electric power grid at the first location.

Optionally, for each second value, the measured voltage comprises a magnitude of the voltage before and after the respective power change, and the measured current comprises a magnitude of the current, and a phase of the current relative to the voltage, before and after the respective power change.

Optionally, determining the third value comprises: selecting an extremum second value from among the plurality of second values; and determining the third value based on the selected extremum second value.

Optionally, determining the third value comprises: fitting a function to the plurality of second values, the function being a function of the ratio of reactive to active power; determining an extremum value of the fitted function; and determining the third value based on the determined extremum value of the fitted function.

Optionally, the method comprises, for each of the plurality of second values: measuring the respective ratio of reactive to active power of the electric power flow in the electric power grid at the first location caused by the respective power change.

Optionally, for each of the plurality of second values, the respective power change provides electric power to or consumes electric power from the electric power grid at the first location with the respective different ratio of reactive to active power.

Optionally, the first value is indicative of a function of reactance and resistance of the electric power grid as observed at the first location.

Optionally, the first value is indicative of an impedance, a short circuit current, or a short circuit level of the electric power grid as observed at the first location.

Optionally, the first value is indicative of a ratio of reactance to resistance of the electric power grid as observed at the first location.

Optionally, the method comprises: determining a fourth value indicative of the ratio of reactive to active power that corresponds to the determined third value; and determining the first value based on the fourth value.

Optionally, determining the fourth value comprises: determining the ratio of reactive to active power that corresponds to the selected extremum second value.

Optionally, determining the fourth value comprises: determining, based on the fitted function, the ratio of reactive to active power that corresponds to the extremum value of the fitted function; an determining the fourth value based on the determined ratio of reactive to active power that corresponds to the extremum value of the fitted function.

Optionally, the method comprises, for each of the plurality of second values: causing one or more power units to perform the respective power change.

Optionally, for each of the plurality of second values, causing the one or more power units to perform the respective power change comprises: causing the one or more power units to be configured to provide electric power to or consume electric power from the electric power grid with a respective different ratio of reactive to active power; and causing the one or more power units to be connected to the electric power grid.

Optionally, the one or more power units comprise a variable resistive load in parallel with a fixed reactor, and wherein, for each of the plurality of second values, causing the one or more power units to perform the respective power change comprises: causing the variable resistive load to be adjusted so that the one or more power units provide electric power to or consume electric power from the electric power grid at the first location with a respective different ratio of reactive to active power.

Optionally, the fixed reactor has a relatively low quality factor, and the method comprises: damping, by the fixed reactor, a power transient caused by the connection of the one or more power units to the electric power grid.

Optionally, the one or more power units comprise a reactor with variable quality factor, and wherein, for each of the plurality of second values, causing the one or more power units to perform the respective power change comprises: causing the variable quality factor to be adjusted so that the one or more power units provide electric power to or consume electric power from the electric power grid at the first location with a respective different ratio of reactive to active power.

Optionally, the one or more power units comprise an inverter, and wherein, for each of the plurality of second values, causing the one or more power units to perform the respective power change comprises: causing the inverter to provide electric power to or consume electric power from the electric power grid at the first location with a respective different ratio of reactive to active power.

Optionally, the method comprises, for each of the second values: obtaining voltage values indicative of the measured voltage of the electric power grid at the first location before and after the respective power change; and obtaining current values indicative of the measured current of the electric power grid at the first location before and after the respective power change; and determining the second value based on the obtained voltage values and the obtained current values.

Optionally, the method comprises: determining, based on the determined first value, one or more settings for a voltage control system for controlling voltage at the first location of the electric power grid by providing to the electric power grid or consuming from the electric power grid reactive and/or active power.

Optionally, the voltage control system comprises the one or more power units.

Optionally, the ratio of reactance to resistance of the electric power grid as observed at a first location of the electric power grid is less than or equal to 10.

Optionally, the third value is indicative of an inflection point of the relationship.

According to a second aspect of the present invention, there is provided a method of determining a first value of a characteristic of an electric power grid as observed at a first location of the electric power grid, the method comprising: obtaining a plurality of second values, each second value being indicative of a relationship between a difference in measured voltage of the electric power grid at the first location before and after a respective power change and a difference in measured current of the electric power grid at the first location before and after the respective power change, each power change causing an electric power flow in the electric power grid at the first location with a respective different ratio of reactive to active power; determining the first value based on the plurality of second values.

According to a third aspect of the present invention, there is provided apparatus configured to perform the method according to the first aspect or the second aspect.

According to a fourth aspect of the present invention, there is provided a system comprising the apparatus according to the third aspect, and the one or more power units.

According to a fifth aspect of the present invention, there is provided a computer program comprising instructions which, when executed by a computing system, causes the computing system to perform the method of the first aspect or the second aspect.

Further features and advantages of the invention will become apparent from the following description of preferred embodiments of the invention, given by way of example only, which is made with reference to the accompanying drawings.

### BRIEF DESCRIPTION OF THE DRAWINGS

FIG. 1 is a flow diagram illustrating a method according to an example;

FIG. 2A is a schematic diagram illustrating an electric power grid according to an example;

FIG. 2B is a schematic diagram illustrating an electric power grid according to an example;

FIG. 3A is a schematic diagram illustrating a plot of a power provided to an electric power grid by a power unit, as a function of time t, according to an example;

FIG. 3B is a schematic diagram illustrating a plot of current as a function of time t over the same time period as in FIG. 3A, according to an example;

FIG. 3C is a schematic diagram illustrating a plot of voltage as a function of time t over the same time period as in FIG. 3A, according to an example;

FIG. 4 is a schematic diagram illustrating a plot of voltage, current, and the phase relationship between voltage and current as a function of time t over a certain time period, according to an example;

FIG. 5 is a schematic diagram illustrating a plot of a change in voltage and a change in current caused by a power change, as a function of an X/R ratio of a modulator, according to an example;

FIG. 6 is a schematic diagram illustrating a plot of a theoretical impedance and a measured impedance, each as a function of an X/R ratio of a modulator, according to an example;

FIG. 7A is a schematic diagram illustrating a plot of a plurality of second values, and a selected extremum second value, according to an example;

FIG. 7B is a schematic diagram illustrating a plot of a plurality of second values, and a function fitted to the plurality of second values, according to an example;

FIG. 8 is a schematic diagram illustrating a plot of a measured impedance and a plot of the error between a theoretical impedance and a measured impedance, each as a function of a shunt load of a modulator, according to an example;

FIG. 9 is a schematic diagram illustrating a power unit, according to an example;

FIG. 10 is a schematic diagram illustrating a measured X/R ratio of an electric power grid as a function of an X/R ratio of a modulator, according to an example;

FIG. 11 is a schematic diagram illustrating impedance, resistance, and reactance as a function of an X/R ratio of a modulator, according to an example;

FIG. 12 is a schematic diagram illustrating a modulator, according to one example;

FIG. 13 is a schematic diagram illustrating a modulator, according to a another example;

FIG. 14 is a flow diagram illustrating a method, according to another example;

FIG. 15 is a schematic diagram illustrating an apparatus, according to an example; and

FIG. 16 is a schematic diagram illustrating a system, according to an example.

### DETAILED DESCRIPTION

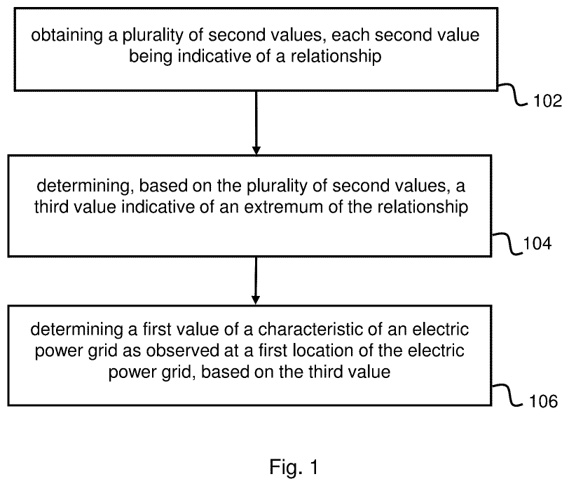

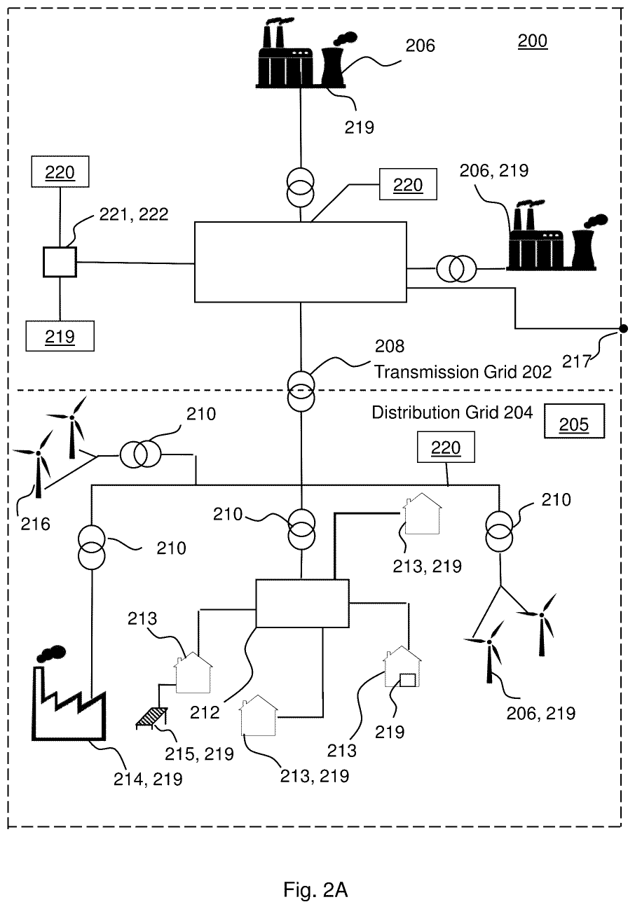

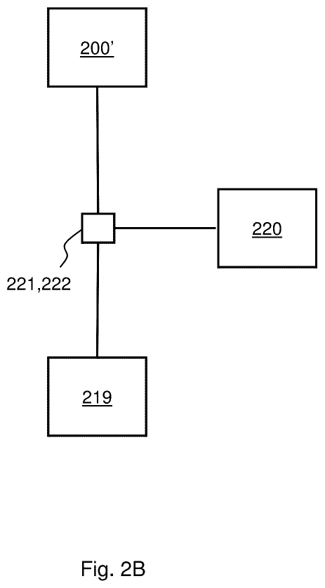

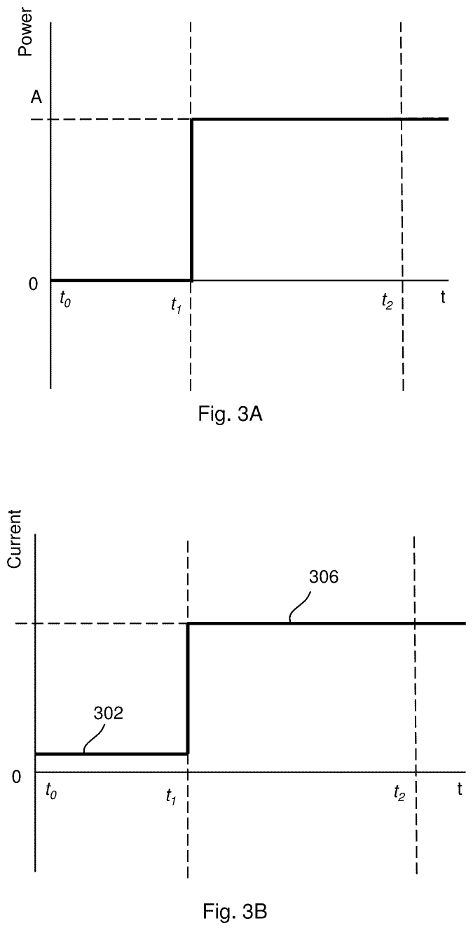

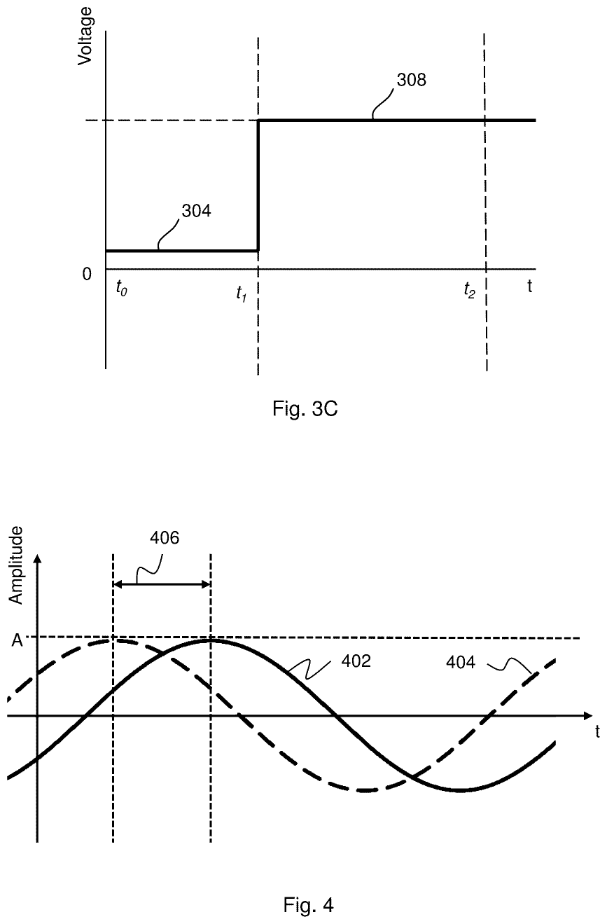

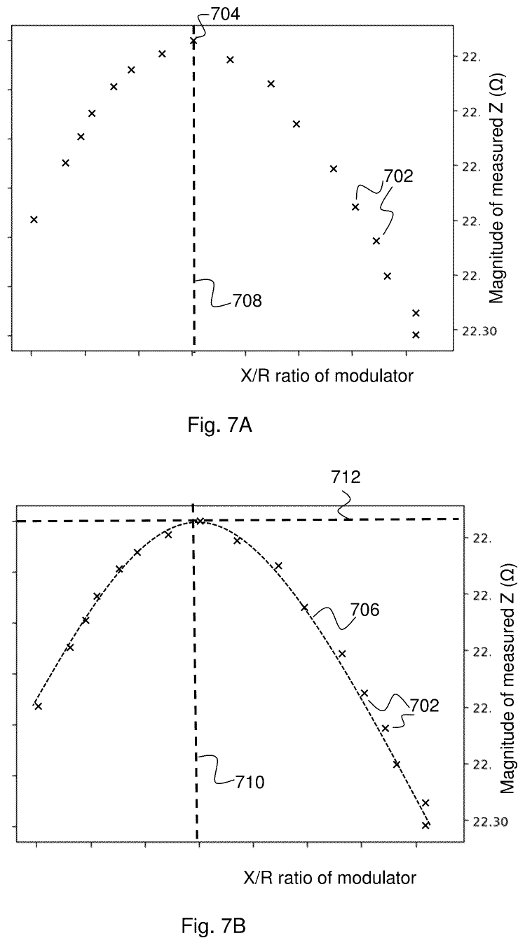

Referring to FIG. 1, there is illustrated a method of determining a first value of a characteristic (e.g. impedance or X/R ratio) of an electric power grid as observed at a first location of the electric power grid (see e.g. the first location 221 of the electric power grid 200 of FIG. 2A). In broad overview, the method comprises:
in step 102, obtaining a plurality of second values (see e.g. the second values 702 of FIG. 7A or 7B), each second value being indicative of a relationship between a difference in measured voltage of the electric power grid at the first location before and after a respective power change (see e.g. the power change A of FIG. 3A) and a difference in measured current of the electric power grid 200 at the first location before and after the respective power change, each power change causing an electric power flow in the electric power grid at the first location with a respective different ratio of reactive to active power;
in step 104, determining, based on the plurality of second values 702, a third value indicative of an extremum of the relationship (see e.g. 704 of FIG. 7A or 712 of FIG. 7B); and
in step 106, determining the first value of the characteristic of the electric power grid as observed at the first location of the electric power grid based on the third value (see e.g. example first values 704, 712 of impedance, or example first values 708, 710 of X/R ratio, of FIGS. 7A and 7B).

As explained in more detail below, determining the first value of the characteristic (e.g. impedance or X/R ratio, although other characteristics are possible) based on the third value indicative of the extremum of the relationship allows for an accurate first value to be determined. Moreover, this is provided even for grids having a relatively low X/R ratio, such as less than 10. Accordingly, an accurate value of the characteristic may be provided for a wide variety of grids. Moreover, the method may provide that this value may be determined on demand.

An accurate first value of the characteristic may, in turn, allow for improved planning and/or maintenance of the proper operation of the power grid, for example. For example, an accurate impedance value may allow for an accurate short circuit current or short circuit level to be determined for the first location. As another example, an accurate X/R ratio may allow for effective voltage compensation to be provided. For example, in certain grids, a voltage control system may be used to compensate changes in voltage, such as a voltage drop. The ratio of reactive to active power to be provided to the grid in order to provide for optimal for voltage compensation may be determined based on an X/R ratio of the grid at the location of the voltage control system. Hence, providing an accurate X/R ratio may help improve the effectiveness and efficiency of the voltage compensation. Other examples are possible.

As mentioned, the method of FIG. 1 is for determining a value of an electric power flow characteristic of an electric power grid. Referring now to FIG. 2A, there is illustrated an electric power grid 200 according to an example.

Supply of electricity from providers such as power stations, to consumers, such
as domestic households and businesses, typically takes place via an electricity distribution network or electric power grid 200. In the example of FIG. 2A, the electric power grid 200 comprises a transmission grid 202 and a distribution grid 204.

The transmission grid 202 is connected to power generators 206, which may be nuclear plants or gas-fired plants, for example, from which it transmits large quantities of electrical energy at very high voltages (typically of the order of hundreds of kV), over power lines such as overhead power lines, to the distribution grid 204. These power generators 206 may also include larger-scale wind farms and/or solar farms. As discussed above, in examples, the transmission grid 202 may have a low X/R ratio. It may therefore be particularly useful to determine an accurate X/R ratio (or impedance, or other characteristic) as observed at first locations 221 that are within the transmission grid 202. However, it will be appreciated that the first location 221 may be any location of the electric power grid 200, and may for example be in the distribution grid 204 or any other part of the electric power grid 200.

The transmission grid 202 is linked to the distribution grid 204 via a transformer 208, which converts the electric supply to a lower voltage (typically of the order of 100 kV or below) for distribution in the distribution grid 204.

The distribution grid 204 is connected via substations 210 comprising further transformers for converting to still lower voltages to local networks which provide electric power to power consuming devices connected to the electric power grid 200. The local networks may include networks of domestic consumers, such as a local community network 212, that supplies power to domestic appliances within private residences 213 that draw a relatively small amount of power in the order of a few kW. Private residences 213 may also use electric vehicles, battery storage, heat pumps, air conditioning devices and photovoltaic devices 215 to provide relatively small amounts of power for consumption either by appliances at the residence or for provision of power to the grid. The local networks may also include industrial premises such as a factory 214, in which larger appliances operating in the industrial premises draw larger amounts of power in the order of several kW to MW. The local networks may also include networks of smaller power generators such as battery storage, solar and wind farms 216 that provide power to the electric power grid. Although, for conciseness, only one transmission grid 202 and one distribution grid 204 are shown in FIG. 2A, in practice a typical transmission grid 202 supplies power to multiple distribution grids 204. One transmission grid 202 may also be interconnected to one or more other transmission grids 202.

Electric power flows in the electric power grid 200 as alternating current (AC),
which flows at a system frequency, which may be referred to as a grid frequency (typically 50 Hz or 60 Hz, depending on the country). The electric power grid 200 operates at a synchronized frequency so that the frequency is substantially the same at each point of the grid.

The grid 200 may include one or more direct current (DC) interconnects 217 that provide a DC connection between the electric power grid 200 and other electric power grids. Typically, the DC interconnects 217 connect to the typically high voltage transmission grid 202 of the electrical power grid 200. The DC interconnects 217 provide a DC link between the various electric power grids, such that the electric power grid 200 defines an area which operates at a given, synchronised, grid frequency that is not affected by changes in the grid frequency of other electric power grids. For example, the UK transmission grid is connected to the Synchronous Grid of Continental Europe via DC interconnects.

The electric power grid 200 may comprise one or more measurement devices 220 for measuring a value of a first parameter of electric power flow in the electric power grid 200, such as grid voltage V and/or current I. The measurement device 220 may be connected to the grid 200 such that the measurement device 220 measures the value of a first parameter of electric power flow in the electric power grid 200 at a particular first location 221, such as at a particular a point of connection 222 to the grid 200. In some examples, the particular first location 221 may be within the transmission grid 202, such as a high voltage portion of the transmission grid (with voltage typically on the order of hundreds of kV). However, as above, the particular first location 221 may be any location of the electric power grid 200, such as within the distribution grid 204 or any other part of the electric power grid 200. Similarly, in examples, the particular point of connection 222 may be within the transmission grid 202, such as a high voltage portion of the transmission grid. However, the particular point of connection 222 may be any point of connection to the electric power grid 200, such as within the distribution grid 204 or any other part of the electric power grid 200. In examples, the measurement device 220 may comprise a phasor measurement unit (PMU), which may be configured to measure one or more of a frequency, voltage, current, power, reactive power, active power, and phase angle of electricity flowing in the electric power grid. Other examples are possible.

The grid 200 comprises a plurality of power units 219. Each power unit 219 is configured to consume electric power from and/or provide electric power to the electric power grid 200. For example, each of the power generators 206, residences 213, photovoltaic devices 215, factory 214, and wind farms 216 may be an example of a power unit 219. Indeed, in examples, any device or other grid asset, or combination or subset of such grid assets, that consume electric power from and/or provide electric power to the electric power grid 200, may be a power unit 219.

Referring to step 102 of the method described above with reference to FIG. 1, as mentioned, each second value is indicative of a relationship between a difference in measured voltage of the electric power grid 200 at the first location 221 before and after a respective power change and a difference in measured current of the electric power grid 200 at the first location 221 before and after the respective power change. Here, each power change causes an electric power flow in the electric power grid 200 at the first location 221 with a respective different ratio of reactive to active power. In examples, each power change may be performed by one or more power units 219. FIG. 2B shows an example arrangement of the point of connection 222 between a power unit 219, a measurement device 220, and a remainder 200′ of the electric power grid 200. Referring to FIG. 2B, the first location 221 of step 102 may be the same as the point of connection 222 between the remainder 200′ of the electric power grid 200 and one or more power units 219 configured to perform a power change as per step 102. In this case, the ratio of reactive to active power provided to or consumed by the one or more power units 219 at the point of connection 222 is the same as, or substantially the same as, the ratio of reactive to active power flowing at the first location 221. As mentioned above, the point of connection 222 may be located at any point in the electric power grid 200, and may in some examples be within the transmission grid 202, the distribution grid 204, or any other part of the electric power grid 200. In examples, as described above, the one or more power units 219 at the point of connection 222 may be any device or other grid asset, or combination or subset of such grid assets, that consume electric power from and/or provide electric power to the electric power grid 200, including existing power units such as power generators 206, residences 213, photovoltaic devices 215, a factory 214, and wind farms.

The configuration of an example power unit 219 is discussed briefly to provide context for the following sections and will be discussed in more detail in later sections. Referring briefly to FIG. 9, there is illustrated an example power unit 219. In this example, the power unit 219 comprises a power device 906, a modulator 904, and a control unit 902. The power device 906 may be any device configured to provide and/or consume electric power, such as any of the examples described above. The modulator 904 is configured to modulate the electric power provided or consumed by the power device 206. In particular, in this example, the modulator 904 is configurable such that the power unit 219 provides electric power to or consumes electric power from the electric power grid 200 with a particular ratio of reactive to active power. For example, the modulator 904 itself may have an associated X/R ratio, which may be configurable such that the power provided to or consumed from the grid by the power unit 219 has a particular ratio of reactive to active power. The modulator 904 may also comprise a switch (not shown in FIG. 9), where the switch may be used to control power flow from and/or to the power unit 219 by connecting or disconnecting the power unit 219 from the grid 200. In this example, the control unit 902 is configured to control the ratio of reactive to active power of the power provided to or consumed from the grid 200 by the power unit 219. In particular, the control unit 902 may control the modulator 904 to modulate the power consumed or provided by the power device 206 so that the power provided to the electric power grid 200 by the power unit 219 or the power consumed by the power unit 219 from the electric power grid 200 has a particular ratio of reactive to active power (for example a particular one of a plurality of ratios of reactive to active power that the modulator 904 is configurable to provide). For example, the control unit 902 may control the modulator 904 to be configured according to a particular one or a plurality of X/R ratios, so that the power provided to or consumed from the grid 200 by the power unit 219 has a particular, corresponding, ratio of reactive to active power. The control unit 902 may also control the modulator 904 to open or close the switch in order to disconnect or connect, respectively, the power unit 219 from or to the grid 200.

Referring to FIG. 3A, there is illustrated an example change in power P provided to the grid 200 at the first location 221 by a power unit 219, for example the power unit 219 of FIG. 9. It will be appreciated that in other examples, power may be consumed from the grid 200 at the first location 221 by a power unit 219. In examples described hereinafter, terms such as the power, current, voltage, and impedance refer specifically to the power, current, and voltage, and impedance as observed at the first location 221. In examples, a switch may be open at time to, such that the power unit 219 is neither consuming power from nor providing power to the grid 200. This continues until time t₁. At time t₁, the switch may be closed, connecting the power unit 219 to the grid 200 and causing the power unit 219 to provide electric power to the electric power grid 200. In this example, at time t₁, the power unit 219 provides power of amplitude A to the grid 200.

The power unit 219 continues to provide power at amplitude A up until and beyond time t₂. In this example, the change in power at time t₁ is instantaneous or practically instantaneous. Accordingly, the power Pas a function of time t takes the form of a step function. In this example, the amplitude of the change in power provided to the grid 200 is +A (where the ‘+’ represents that the change is an increase in power provided to the grid 200), and the time of the change is t₁. In other examples, the amplitude of the change in power consumed from and/or provided to the grid 200 may be −A (where the ‘−’ represents that the change is a decrease in power provided to the grid 200, or an increase in power consumed from the grid 200).

Referring to step 102 of the method described above with reference to FIG. 1, as mentioned, for each of the plurality of second values, each change in power P provided to the grid 200 at the first location 221 has a respective different ratio of reactive to active power. FIG. 3A does not show the ratio of reactive to active power, but instead illustrates the apparent power P for an example particular ratio of reactive to active power.

Referring to FIGS. 3B and 3C, there is illustrated an example of a respective change in current and voltage at the first location 221 caused by the example power change shown in FIG. 3A. Referring to FIG. 3B, at time t₀, the current has an initial magnitude 302, where the complex-valued current is given by:

$${I}^{pre} = {I}_{d}^{pre} - {jI}_{q}^{pre} \qquad ( 3 )$$

where

$${I}_{d}^{pre}$$

is the active current and

$${I}_{q}^{pre}$$

is the reactive current. In some examples, I^{pre} is assumed to be zero. In some examples, noise may contribute to I^{pre}, resulting in a non-zero value, which may be filtered out during post-processing.

Referring to FIG. 3C, at time to, the voltage has an initial magnitude 304, where the complex-valued voltage is given by:

$${U}^{pre} = {U}_{s} + {I}^{pre} ( {R}^{th} + j {X}^{th} ) \qquad ( 4 )$$

where Uₛ is a constant value representing an apparent voltage source arising from contributions from the wider electric power grid 200, typically assumed to have no imaginary component, Uₛ=Uₛ+j0. Referring to FIG. 2B, Uₛ may be the apparent voltage source of the remainder 200′ of the electric power grid 200, as observed from the first location 221. In practice, the value of Uₛ is typically unknown.

Referring to equation 1, the impedance Z as observed at the first location 221 may be defined as Z=R^{th}+jX^{th}, where R^{th} and X^{th} are the Thevenin resistance and reactance at the first location 221, respectively. In practice, R^{th} and X^{th} are unknowns that may be determined based on measurements of I^{pre}, I^{post}, |U^{pre}|, and |U^{post}|, as discussed in the following sections.

Referring to both FIGS. 3B and 3C, the current and voltage remain at the initial respective values of I^{pre} and U^{pre} until time t₁. At time t₁, due to the increase in power+A provided to the grid 200 at the first location 221 by the power unit 219, the current and voltage increase. At time t₂, the current has a final magnitude 306, where the complex-valued current is given by:

$${I}^{post} = {I}_{d}^{post} - {jI}_{q}^{post} \qquad ( 5 )$$

At time t₂, the voltage has a final magnitude 308, where the complex-valued voltage is given by:

$${U}^{post} = {U}_{s} + {I}^{post} ( {R}^{th} + j {X}^{th} ) \qquad ( 6 )$$

FIGS. 3B and 3C illustrate the respective current and voltage changes in the form of a step function. It will be appreciated that this is for illustrative purposes and that the increase in current and voltage need not necessarily be instantaneous. Additionally, in practice, the voltage and current may exhibit transients or other deviations from steady state behaviour. In some examples, the time t₂ may be chosen such that any deviations from steady state are sufficiently small enough to be neglected, such that the voltage and current have settled at the respective values of I^{post} and U^{post} at time t₂. Combining equation 4 and equation 6, the impedance Z (as also defined in equation 1) may be expressed as:

$$Z = \frac{{U}^{post} - {U}^{pre}}{{I}^{post} - {I}^{pre}} \qquad ( 7 )$$

For clarity, equation 7 will be referred to hereinafter as the theoretical impedance, Z_{T}.
It will be appreciated that equation 1 and equation 7 represent the same physical quantity of impedance Z, expressed in terms of different grid characteristics. In particular, equation 7 refers to the Thevenin equivalent method of determining the impedance Z. In practice, the theoretical impedance Z_{T} cannot be measured directly, as the angle of the current may, in practice, only be measurable relative to the angle of the voltage (or vice versa). That is, the absolute angle of both the voltage and the current is not known without additional reference waveforms, as discussed in the following section. FIG. 4 illustrates an example relationship between current and an associated voltage varying at a fixed angular frequency ω, typical of an AC circuit. Referring to FIG. 4, there is a plot 402 of current as a function of time t. In this example, the current has the form cos(t) with a global phase angle Φ_{I},

$$I ( t ) = A cos ( ω t + {Φ}_{I} ) \qquad ( 8 )$$

where A is the amplitude of the current. FIG. 4 also includes a plot 404 of voltage as a function of time t. Similarly, the voltage may be represented as a sinusoidal function,

$$V ( t ) = A cos ( ω t + {Φ}_{V} ) \qquad ( 9 )$$

where A is the amplitude of the voltage. It will be appreciated that in practice, the voltage and current need not have the same amplitude. FIG. 4 illustrates a phase delay 406 between the voltage and current, the phase delay 406 corresponding to a relative phase angle Φ=Φ_{V}−Φ₁ when expressed in degrees. When the power flowing in the grid 200 is purely active power, the associated phase angle is zero, and the current and the voltage are in phase. When the power flowing in the grid is purely reactive power, the associated phase angle is ninety degrees. If the grid is dominated by inductive loads, the current lags the voltage at angles tending to ninety degrees. If the grid is dominated by capacitive loads, the current leads the voltage by angles tending to ninety degrees.

Because a phase angle is defined relative to a known reference point, Φ_{V} and Φ₁ cannot, in practice, both be defined without two independent reference points. In practice, in examples, the voltage waveform may be used as the reference point and the voltage phase angle Φ_{V} is treated as a fixed parameter, typically set to zero. In other examples, the current waveform may be used as the reference point and hence the current phase angle Φ_{V} is treated as the fixed parameter. In both cases, at least one of the phase angles is chosen to be a fixed parameter. Consequently, in practice, it is difficult to directly and/or accurately measure the theoretical impedance Z_{T}.

Instead, the following assumption may be used to estimate the impedance Z:

$$Z \approx \frac{\vert {U}^{post} \vert - \vert {U}^{pre} \vert}{{I}^{post} - {I}^{pre}} \qquad ( 10 )$$

For clarity, equation 10 will be referred to as the measured impedance, Z_{M}. In this example, the voltage phase angle Φ_{V} is assumed to be zero. This means that the measured voltage is assumed to have no reactive component, and there is no change in angle between the initial and final voltage values. Hence, the active current may be measured to be that proportion of the current which is in phase with the measured voltage. Similarly, the reactive current may be measured to be that proportion of the current which is ninety degrees out of phase with the measured voltage. As an aside, it is noted that the right hand side of equation 10 is an example of a relationship between a difference in measured voltage of the electric power grid at the first location 221 before and after a respective power change (i.e. |U^{post}|−|U^{pre}|) and a difference in measured current of the electric power grid 200 at the first location 221 before and after the respective power change (i.e. I^{post}−I^{pre}), as per step 102 of FIG. 1. In this example, the relationship is a ratio, as per equation 10. The measured impedance Z_{M} of equation 10 is an example of a second value indicative of the relationship, as per step 102 of FIG. 1.

Equation 7 and equation 10 are equal only when the numerator of equation 7 has a vanishing imaginary component. When this condition is satisfied, the measured impedance Z_{M} is equal to the theoretical impedance Z_{T}. Using equations 3 to 6, the numerator of equation 7 can be expressed as:

$${U}^{post} - {U}^{pre} = [ ( {I}_{d}^{post} - {I}_{d}^{pre} ) - j ( {I}_{q}^{post} - {I}_{q}^{pre} ) ] ( {R}^{th} + j {X}^{th} ) \qquad ( 11 )$$

Similarly, the numerator of equation 10 can be expressed as:

$$\vert {U}^{post} \vert - \vert {U}^{pre} \vert = \vert {U}_{s} + {I}^{post} ( {R}^{th} + j {X}^{th} ) \vert - \vert {U}_{s} + {I}^{pre} ( {R}^{th} + j {X}^{th} ) \vert \qquad ( 12 )$$

Setting the imaginary component of equation 11 to zero, which imposes the condition for the measured impedance Z_{M} to match the theoretical impedance Z_{T}:

$$( {I}_{d}^{post} - {I}_{d}^{pre} ) {X}^{t h} - ( {I}_{q}^{post} - {I}_{q}^{pre} ) {R}^{th} = 0 \qquad ( 13 )$$

Rearranging equation 13 gives the following condition:

$$\frac{{X}^{t h}}{{R}^{th}} = \frac{{I}_{q}^{post} - {I}_{q}^{pre}}{{I}_{d}^{post} - {I}_{d}^{pre}} \qquad ( 14 )$$

This shows that where the measured impedance Z_{M} is equal to the theoretical impedance Z_{T}, the ratio of reactive to active power at a first location 221 is equal to the X/R ratio of the grid 200 as observed at the first location 221. Hence, by tuning the ratio of reactive to active power, such that the measured impedance Z_{M} matches the theoretical impedance Z_{T}, an accurate value of the X/R ratio of the grid 200 as observed at the first location 221 can be determined. Further, tuning the ratio of reactive to active power so that the measured impedance Z_{M} matches the theoretical impedance Z_{T} alternatively or additionally allows for the impedance Z of the grid 200 as observed at the first location 221 to be more accurately measured (that is, allows the theoretical impedance Z_{T} to be determined). Accordingly, in examples, the method may provide for an accurate determination of a value of the impedance and/or the X/R ratio of the grid 200 as observed at the first location 221. The following sections will discuss the method by which the ratio of reactive to active power is tuned so that the measured impedance Z_{M} matches the theoretical impedance Z_{T}.

The theoretical impedance Z_{T} at the first location 221 is independent of the ratio of reactive to active power at the first location 221. A change in the ratio of reactive to active power causes a change in the angle of the voltage and a change in the angle of the corresponding current. However, from Ohm's Law, the change in the complex current and the change in the complex voltage in a conductor are directly proportional. Therefore, the numerator and the denominator of equation 7 are directly proportional. Hence, the theoretical impedance Z_{T}, or the ratio of the numerator and denominator of equation 7, is constant with any change of the ratio of reactive to active power at the first location 221.

FIG. 6 illustrates a plot of a magnitude of a theoretical impedance Z_{T} 604 and a magnitude of a measured impedance Z_{M} 602 at a first location 221 in the power grid, as a function of an X/R ratio of a modulator 904 of a power unit 219, according to an example. As also discussed elsewhere herein, each X/R ratio of the modulator 904 corresponds to a particular ratio of reactive to active power of the power provided by the power unit 219 to the grid 200 at the first location 221 or of power consumed by the power unit 219 from the grid 200 at the first location 221. The theoretical impedance Z_{T} 604 is a horizontal line, showing that the theoretical impedance Z_{T} is a constant as a function of the X/R ratio of the modulator 904. Accordingly, the theoretical impedance Z_{T} is constant with any change of the ratio of reactive to active power, as discussed above.

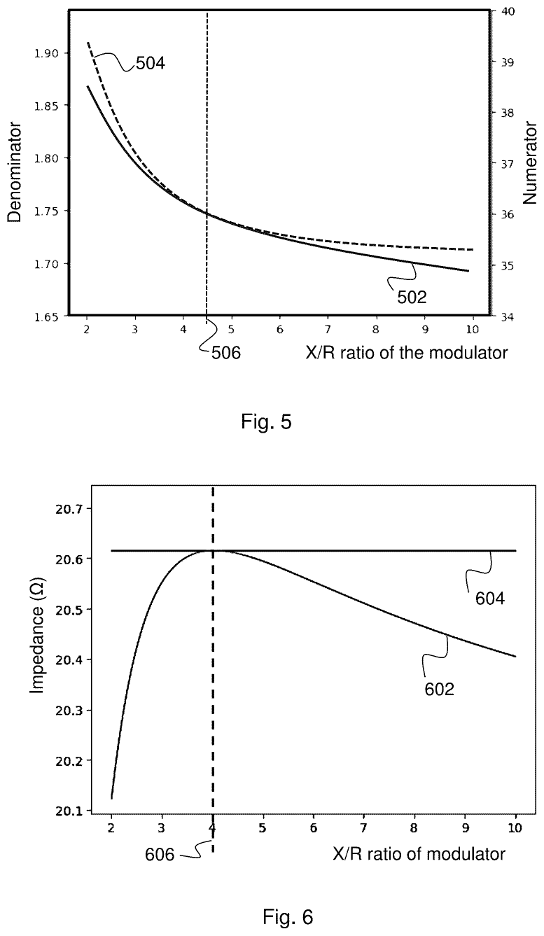

This is not necessarily true for the measured impedance, Z_{M}. Instead, as shown in equation 10, for the measured impedance Z_{M}, there is no change in the angle of the voltage before and after the power change. FIG. 5 illustrates a plot of the magnitude of the numerator 502 and denominator 504 of equation 10, that is, the measured impedance Z_{M}, as a function of the X/R ratio of a modulator 904. It may also be appreciated, referring to equation 10, that the plot 502 represents the absolute change in the magnitude of the voltage before and after the power change. Similarly, the plot 504 represents the absolute change in the complex-valued current before and after the power change. The plot of the numerator 502 and the plot of the denominator 504 have different gradients, except at one X/R ratio of the modulator 904 illustrated by the vertical line 506. Hence, the measured impedance Z_{M}, or the ratio of the numerator and denominator of equation 10, is not a constant as a function of the ratio of reactive to active power.

When the X/R ratio takes the value of the vertical line 506 in FIG. 5, the ratio of reactive to active power is such that the current at the first location 221 has no change in angle before and after the power change. This means that at this point, there is a stationary point in the ratio of the numerator 502 and denominator 504 of equation 10 as a function of the X/R ratio of the modulator 904.

As illustrated in FIG. 5, gradient of the numerator 502 of equation 10 is always less than or equal to the magnitude of the numerator of equation 7. This can be shown mathematically from the triangle inequality applied to two complex numbers z and w:

$$\vert z - w \vert \geq \vert \vert z \vert - \vert w \vert \vert \qquad ( 15 )$$

Therefore, as the respective denominators of equations 7 and 10 are the same, and applying this inequality to the numerators of equation 7 and 10, this implies:

$$\vert {Z}_{T} \vert \geq \vert {Z}_{M} \vert \qquad ( 16 )$$

This is illustrated in FIG. 6, where the measured impedance Z_{M} 602 is always less than or equal to the theoretical impedance Z_{T} 604. As discussed above, the measured impedance Z_{M} is equal to the theoretical impedance Z_{T} when the imaginary component of the numerator of equation 7 is set to zero, shown by the vertical line 606. Equation 14 shows that the measured impedance Z_{M} is maximal when this condition is satisfied. Hence, the maximum value of Z_{M} at the first location 221 corresponds to the theoretical impedance Z_{T} as observed at the first location 221 in the grid.

Hence, the theoretical impedance Z_{T} can be determined by determining the maximum measured impedance Z_{M} as a function of the ratio of reactive to active power at the first location 221. From equation 14, the ratio of reactive to active power at a first location 221 is shown to be equal to the X/R ratio of the grid as observed at the first location 221 when the measured impedance is maximal. Hence, the X/R ratio of the grid as observed at the first location 221 can be determined by determining the ratio of reactive to active power at the first location 221 corresponding to the maximum measured impedance Z_{M}.

By determining the maximum value of Z_{M} as a function of the ratio of reactive to active power, an accurate value of the measured impedance Z_{M} (i.e. the theoretical impedance Z_{T}) can be determined. Additionally, by determining the ratio of reactive to active power corresponding to the maximum value of Z_{M}, and referring to equation 14, an accurate value of the grid X/R ratio can be determined. Equivalently, the maximum value of Z_{M} corresponds to a reduced error between the theoretical impedance Z_{T} and true X/R ratio of the grid and the corresponding determined impedance and determined X/R ratio of the grid, respectively, as observed at the first location 221.

This may be compared to known methods of determining the impedance of an electric power grid which may solely estimate the magnitude of the impedance. Additionally, known methods may assume that the resistance can be neglected when determining the magnitude of the impedance. This method accounts for both the reactive and resistive components of the impedance, hence improving the accuracy of the determined complex-valued impedance and the determined magnitude of the impedance. This improvement may be particularly notable for electric power grids with X/R ratios less than 10, where the contribution from the resistance becomes more significant. Further, a known method only estimates the X/R ratio during a fault event. However, the present technique allows the X/R ratio to be determined during steady state operation of the grid, enabling the grid X/R ratio to be determined on demand.

As mentioned, the method of FIG. 1 comprises, in step 102, obtaining a plurality of second values, each second value being indicative of a relationship between a difference in measured voltage of the electric power grid 200 at the first location 221 before and after a respective power change and a difference in measured current of the electric power grid 200 at the first location 221 before and after the respective power change, each power change causing an electric power flow in the electric power grid 200 at the first location 221 with a respective different ratio of reactive to active power.

For example, the right hand side of equation 10 is an example of a relationship between the difference in measured voltage of the electric power grid at the first location 221 before and after a respective power change (i.e. |U^{post}|−|U^{pre}|) and a difference in measured current of the electric power grid 200 at the first location 221 before and after the respective power change (i.e. I^{post}−I^{pre}), as per step 102 of FIG. 1. In this example, the relationship is a ratio, as per equation 10. The measured impedance Z_{M} of equation 10 is an example of a second value indicative of the relationship. Accordingly, the relationship of step 102 may be indicative of the measured impedance (e.g. Z_{M}), as described above with reference to equation 10. The measured current may be the measured current before and after the power change, as described above with reference to FIG. 3B. The measured voltage may be the measured voltage before and after the power change, as described above with reference to FIG. 3C.

In some examples, the method may comprise, for each of the second values, obtaining voltage values indicative of the measured voltage of the electric power grid at the first location 221 before and after the respective power change (e.g. |U^{post}| and |U^{pre}|); obtaining current values indicative of the measured current of the electric power grid at the first location 221 before and after the respective power change (e.g. and I^{pre}); and determining the second value based on the obtained voltage values and the obtained current values (e.g. Z_{M} as per equation 10.

In some examples, obtaining the voltage values and the current values may comprise measuring at least one value at the first location 221. For example, this may be performed by a measurement device 220 located at the first location 221. In examples, the voltage values and the current values may be obtained from, or derived from the output of, one or more of the measurement devices 220. For example, a PMU may measure one or more of a current, voltage, and phase angle of electricity flowing in the electric power grid. Each measurement device 220 may transmit measured data to a computing system. In examples, each value may be provided or otherwise associated with a time at which the value was measured.

In some examples, obtaining a voltage value indicative of the measured voltage of the electric power grid at the first location 221 before and after the respective power change may comprise obtaining a first voltage value (e.g. |U^{pre}|) at the first location 221 before the particular power change, obtaining a second voltage value (e.g. |U^{post}|) at the first location 221 after the particular power change, and determining a voltage value indicative of the measured voltage of the electric power grid at the first location 221 before and after the respective power change based on the first voltage value and the second voltage value. The first voltage value may be the voltage described above in equation 4, with reference to FIG. 3C. The second voltage value may be the voltage described above in equation 6, with reference to FIG. 3C. For example, determining the voltage value indicative of the measured voltage of the electric power grid at the first location 221 before and after the respective power change may comprise calculating the difference between the magnitude of the first voltage value and the magnitude of the second voltage value (e.g. |U^{post}|−|U^{pre}|)).

In some examples, obtaining a current value indicative of the measured current of the electric power grid at the first location 221 before and after the respective power change may comprise obtaining a first current value (e.g. I^{pre}) at the first location 221 before the particular power change, obtaining a second current value (e.g. I^{post}) at the first location 221 after the particular power change, and determining a current value indicative of the measured current of the electric power grid at the first location 221 before and after the respective power change based on the first current value and the second current value. The first current value may be the current described above in equation 3, with reference to FIG. 3B. The second current value may be the voltage described above in equation 5, with reference to FIG. 3B. For example, determining the current value indicative of the measured current of the electric power grid at the first location 221 before and after the respective power change may comprise calculating the difference between the first current value and the second current value (e.g. I^{post}−I^{pre}).

In examples, each second value may be indicative of a ratio of the difference in the magnitude of the measured voltage (e.g. I^{post}|−|U^{pre}|) of the electric power grid at the first location 221 before and after the respective power change to the difference in measured current (e.g. I^{post}−I^{pre}) of the electric power grid at the first location 221 before and after the respective power change. For example, referring to equation 10, each second value may be indicative of the measured impedance (e.g. Z_{M}). In examples, each second value may be the magnitude of the measured impedance, such as the magnitude of the measured impedance (e.g. |Z_{M}|).

In some examples, for each second value, the measured voltage may comprise a magnitude of the voltage before and after the respective power change, and the measured current may comprise a magnitude of the current, and a phase of the current relative to the voltage, before and after the respective power change. For example, step 102 may comprise measuring the magnitude of the voltage (e.g. |U^{pre}|) and the magnitude of the current (e.g. |I^{pre}|) before the respective power change, measuring the magnitude of the voltage (e.g. |U^{post}|) and the magnitude of the current (e.g. |I^{post}|) after the respective power change, and measuring a phase of the current relative to the voltage, before and after the respective power change. In this example, the complex-valued current (e.g. I^{post} and I^{pre}) may be determined based on the magnitude of the current values and the phase of the current relative to the voltage. This choice of measurements allows the second values to be determined for non-zero and non-controllable currents before the power change. In this example, each second value may be indicative of the measured impedance (e.g. Z_{M}), for example as described in equation 10. In some examples measuring the magnitude of the voltage may comprise measuring the RMS voltage at the first location 221. In some examples, measuring the magnitude of the current may comprise measuring the RMS current at the first location 221.

Referring to FIG. 7A, there is illustrated a plurality of second values 702, each second value obtained with a respective different X/R ratio of a modulator, according to an example. In this example, the modulator may be the modulator 904 of the power unit 219. As discussed above, each X/R ratio of the modulator 904 may correspond to a respective different ratio of reactive to active power of power flowing at the first location 221. Accordingly, each second value 702 in FIG. 7A is determined for a respective power change that causes an electric power flow in the electric power grid at the first location 221 with a respective different ratio of reactive to active power. Referring to FIG. 2B, in examples where both the power unit 219 and the measurement device 220 are connected to the grid at the first location 221, the ratio of reactive to active power of the power flow at the first location 221 may be the same as, or substantially the same as, the ratio of reactive to active power of the power provided by the power unit 219 to the grid 200 or of the power consumed by the power unit 219 from the grid 200. In the example of FIG. 7A, each second value is indicative of the magnitude of the measured impedance (e.g. |Z_{M}|). For example, each second value may have been determined based on equation 10. It will be appreciated that while fewer than twenty second values are shown in FIG. 7A for clarity, in examples there may be hundreds or thousands or more second values. As can be seen from FIG. 7A, changing the ratio of reactive to active power causes respective changes in the measured impedance. In this example, there is a particular ratio of reactive to active power, illustrated by the vertical line 708, that causes a maximum in the measured impedance.

As mentioned, the method of FIG. 1 comprises, in step 104, determining, based on the plurality of second values, a third value indicative of an extremum of the relationship. In some examples, the third value may be indicative of an inflection point of the relationship.

In examples where each second value is indicative of a ratio of the difference in measured voltage of the electric power grid at the first location 221 before and after the respective power change to the difference in measured current of the electric power grid at the first location 221 before and after the respective power change (as per FIG. 7A), the third value may be indicative of a maximum of the ratio. For example, determining the third value may comprise determining the maximum value of the measured impedance (e.g. Z_{M} of equation 10) or of the magnitude of the measured impedance (e.g. |Z_{M}|).

In examples, step 104 may comprise selecting an extremum second value from among the plurality of second values 702, and determining the third value based on the selected extremum second value.

As an example, referring again to FIG. 7A, a maximum second value 704 may be selected from among the plurality of second values 702. In this example, the third value may be determined based on the selected maximum second value 704. In this example, the second values are the magnitude of the measured impedance (e.g. |Z_{M}|). Hence, the third value may be the maximum value of the magnitude of the measured impedance. In some examples, a sorting algorithm may be used to select an extremum second value from among the plurality of second values. In some examples, a measurement device 220 may transmit voltage values and the current values to a computing system. The computing system may determine the second values based on the measured voltage values and the current values and select a maximum second value. This method may allow the third value to be determined in a computationally inexpensive manner. As mentioned, in some examples, the third value may be indicative of an inflection point of the relationship. In the example of FIG. 7A, the maximum second value 704 corresponds to an inflection point in the relationship, specifically in the measured impedance as a function of the ratio of reactive to active power. In some examples, the method may comprise determining an inflection point of the relationship based on the plurality of second values. For example, the second value 704 may be selected based on a determination that one or more second values corresponding to lower ratios of reactive to active powers than for selected second value 704 are lower than the selected second value 704 and one or more second values corresponding to higher ratios of reactive to active powers than for the selected second value 704 are lower than the selected second value 704. Other examples are possible.

As another example, step 104 may comprise fitting a function to the plurality of second values, the function being a function of the ratio of reactive to active power; determining an extremum value of the fitted function; and determining the third value based on the determined extremum value of the fitted function.

For example, fitting a function to the plurality of second values may comprise using the obtained plurality of second values in a model, and fitting the modelled function to the obtained plurality of second values. The model may have one or more parameters, and the fitting may comprise optimising the parameters to fit the model to the obtained second values. In examples, the function may be a polynomial function fitted to the plurality of second values. For example, a parameter representing the difference between the measured second values and the corresponding points in the model may be minimised. For example, a least squares fitting procedure may be used. Other fitting procedures may be used. In examples, determining the extremum value of the fitted function may comprise determining the value of the fitted function at a stationary point or an inflection point of the fitted function. In examples, the stationary point may be determined by either numerical and/or analytical differentiation of the fitted function. In some examples, gradient descent methods may be used to determine the extremum value of the function. Other methods may be used.

As an example, FIG. 7B illustrates the plurality of second values 702 of FIG. 7A, and a function 706 fitted to the plurality of second values 702. As in FIG. 7A, each second value in FIG. 7B was obtained with a respective different X/R ratio of the modulator 904, and hence for a power flow having a respective different ratio of reactive to active power. In this example, the function 706 reaches a maximum value 712 at a particular value 710 of the X/R ratio of the modulator 904. In this example, the third value may be determined based on the determined maximum value 712 of the fitted function. In cases where the second values are the magnitude of the measured impedance, the third value may be indicative of a maximum value of the magnitude of the measured impedance. It will be appreciated that the selected maximum second value 704 of FIG. 7A and the maximum value 712 of the fitted function need not necessarily be the same. In particular, because fitting a function to the data provides interpolation of the data, this may provide a more precise value of the maximum. Additionally, this method may be more resilient to noise effects. Hence, this method may allow for a more accurate determination of the third value, particularly when the number of second values is limited. As mentioned, in some examples, the third value may be indicative of an inflection point of the relationship. In the example of FIG. 7B, the maximum value 712 of the fitted function 706 corresponds to an inflection point in the relationship, specifically in the measured impedance as a function of the ratio of reactive to active power. In some examples, the method may comprise determining the inflection point of the relationship based on the plurality of second values. For example, the inflection point of the fitted function 706 may be determined using numerical and/or analytical differentiation of the fitted function 706, for example as described above. Other examples are possible.

In examples, each second value may be the Thevenin equivalent of the measured impedance Z_{M}, where the Thevenin equivalent of the measured impedance Z_{M} may refer to the ratio of the change in voltage and the change in current before and after a power change. For example, each second value may be given by the approximation of equation 10, reproduced below:

$$Z \approx \frac{\vert {U}^{post} \vert - \vert {U}^{pre} \vert}{{I}^{post} - {I}^{pre}} \qquad ( 10 )$$

In this example, the current phase angle Φ_{V} is assumed to be zero, as the voltage waveform is taken as the refence point. In examples, each second value may be the magnitude of the Thevenin equivalent of the measured impedance, such as the magnitude of the measured impedance of equation 10. For example, step 102 may comprise measuring the magnitude of the voltage (e.g. |U^{pre}|) and the magnitude of the current (e.g. |I^{pre}|) before the respective power change, measuring the magnitude of the voltage (e.g. |U^{post}|) and the magnitude of the current (e.g. |I^{post}|) after the respective power change, and measuring a phase of the current relative to the voltage before and after the respective power change. In this example, the complex-valued current (e.g. |I^{post}| and |I^{pre}|) may be determined based on the magnitude of the current values and the phase of the current relative to the voltage.

Although in some of the above examples the Thevenin equivalent of the measured impedance is used, it will be appreciated that this need not necessarily be the case. In other examples, each second value may be the Norton equivalent of the measured impedance Z_{M}. For example, each second value may be given by the approximation:

$$Z \approx \frac{{U}^{post} - {U}^{pre}}{\vert {I}^{post} \vert - \vert {I}^{pre} \vert} \qquad ( 17 )$$

In this example, the current phase angle Φ₁ is assumed to be zero, as the current waveform is taken as the refence point. In examples, each second value may be the magnitude of the Norton equivalent of the measured impedance, such as the magnitude of the measured impedance of equation 17. For example, step 102 may comprise measuring the magnitude of the voltage (e.g. |U^{pre}|) and the magnitude of the current (e.g. |I^{pre}|) before the respective power change, measuring the magnitude of the voltage (e.g. |U^{post}|) and the magnitude of the current (e.g. |I^{post}|) after the respective power change, and measuring a phase of the voltage relative to the current before and after the respective power change. In this example, the complex-valued voltage (e.g. U^{post} and U^{pre}) may be determined based on the magnitude of the voltage values and the phase of the voltage relative to the current.

In examples, the accuracy of the estimate of equation 17 may be improved by ensuring that the current is sufficiently stable such that the current before the power change (e.g. |I^{pre}|) may be reasonably approximated to zero. For example, there may be components in the grid between the modulator 904 and the first location 221 that cause noise in the system. Hence, reducing the load in the system between the modulator 904 and the first location 221 may reduce the magnitude of the initial current, allowing it to be approximated to zero. In this example, where the second values are indicative of the Norton equivalent of the measured impedance (e.g. equation 17), determining the third value may comprise determining a maximum based on the plurality of second values.

Each second value need not necessarily be indicative of a ratio in the difference in measured voltage before and after the respective power change to the difference in measured current before and after the respective power change.

For example, in other examples, each second value may be indicative of a difference between a first and second parameter. For example, the first parameter may be indicative of the difference in measured voltage of the electric power grid at the first location 221 before (e.g. U^{pre}) and after (e.g. U^{post}) the respective power change. The second parameter may be indicative of the difference in measured current of the electric power grid at the first location 221 before (e.g. I^{pre}) and after (e.g. I^{post}) the respective power change. For example, the first parameter may be the magnitude of the difference between the magnitude of the measured voltage before and after the respective power change. For example, the second parameter may be the magnitude of the difference between the measured current before and after the respective power change, scaled by some constant value.

In this example, each second value may be given by:

$${Z}_{est} * \vert ( Ipost - Ipre ) \vert - \vert \vert Upost \vert - \vert Upre \vert \vert \qquad ( 18 )$$

In this example, Zₑₛₜ may be an estimate of the theoretical impedance (e.g. Z_{T}) of the grid. This scaling value is useful to scale the first and second term in equation 18, so that the first and second term have a similar magnitude. This may improve the determination of an extremum value of equation 18. In this example, determining the third value may comprise determining a minimum of the difference. In this example, where the second values are given by equation 18, determining the third value may comprise selecting the minimum second value from among the plurality of second values. Other examples of second values are possible.

In some examples, the method of FIG. 1 comprises, for each of the plurality of second values, measuring the respective ratio of reactive to active power of the electric power flow in the electric power grid 200 at the first location 221 caused by the respective power change. In examples, the reactive power at the first location 221, and the active power at the first location 221 may be obtained from, or derived from the output of, one or more of the measurement devices 220. This may allow the X/R ratio of the grid 200 as observed at the first location 221 to be determined without necessarily knowing or measuring the X/R ratio of the modulator 904 or the ratio of reactive to active power provided or consumed by the power unit 219. For example, the power unit 219 need not necessarily be located at the first location 221. In this example, the ratio of reactive to active power provided or consumed by the power unit 219 may not be the same as the ratio of reactive to active power at the first location 221. This may be a result of the presence of components in the grid 200, such as transformers, between the power unit 219 and the first location 221. Hence, by measuring the ratio of reactive to active power at the first location 221, this may reduce the need for additional circuit calculations and/or may improve the accuracy of the determined first value (e.g. X/R ratio or impedance).

In some examples, where the power unit 219 is not necessarily be connected at the first location 221, circuit calculations may be performed to determine the ratio of reactive and active power at the first location 221 based on the additional components between the first location 221 and the power unit 219 and the X/R ratio of the modulator 904. In some examples, the ratio of reactive to active power at the first location 221 may simply be assumed to be the same as the ratio of reactive to active power provided to or consumed by the power unit 219.

In some examples, referring to the method of FIG. 1, for each of the plurality of second values, the respective power change provides electric power to or consumes electric power from the electric power grid 200 at the first location 221 with the respective different ratio of reactive to active power. For example, the ratio of reactive to active power provided or consumed by the power unit 219 may be the same as the ratio of reactive to active power of the grid at the first location 221. This allows the ratio of reactive to active power at the first location 221 to be determined based on the ratio of reactive to active power provided to or consumed by the power unit 219. For example, referring again to FIG. 2B, this may be the case where the measurement unit 220 and the power unit 219 are both connected to the first location 221, that is, share a common point of connection 222 to the grid 200. In examples, the ratio of reactive to active power at the first location 221 may be determined based on the X/R ratio of the modulator 904. For example, as described in more detail below, determining the ratio of reactive to active power at the first location 221 may comprise determining a shunt load of the modulator 904, and determining the ratio of reactive to active power at the first location 221 based on the shunt load of the modulator 904. In examples, determining the ratio of reactive to active power at the first location 221 in the electric power grid may comprise determining the settings of the modulator 904, and determining the ratio of reactive to active power at the first location 221 based on the settings of the modulator 904. This may allow the ratio of reactive to active power at the first location 221 to be determined in a cost effective and computationally inexpensive manner.

As mentioned, the method of FIG. 1 comprises, in step 106, determining the first value of the characteristic of the electric power grid 200 as observed at the first location 221 of the electric power grid based on the third value (e.g. the maximum second value, e.g. the maximum measured impedance).

In some examples, the first value may be indicative of a function of reactance and resistance of the electric power grid as observed at the first location 221. For example, such functions of reactance and resistance may include the measured impedance, the X/R ratio, a short circuit current, and a short circuit level, as described in more detail below.

In some examples, the first value is indicative of the measured impedance of the electric power grid as observed at the first location 221. For example, referring to FIG. 7A, the first value may be the selected maximum second value 704, where the maximum second value 704 is the maximum value of the magnitude of the measured impedance. In this example, the first value is the same as the third value. Referring to equation 16, the maximum value of the measured impedance corresponds to the theoretical impedance Z_{T} of the electric power grid as observed at the first location 221. Accordingly, this method provides an accurate determination of the impedance of the electric power grid as observed at the first location 221.

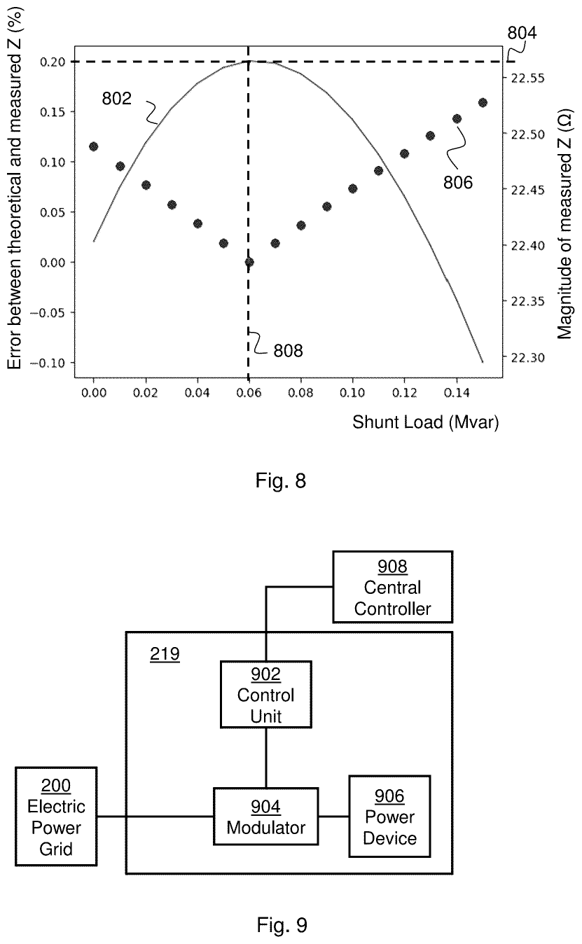

As an example, FIG. 8 illustrates a plot 802 of the magnitude of the measured impedance at the first location 221 as a function of a shunt load of a modulator 904 of the power unit 219. For clarity, the magnitude of the measured impedance at the first location 221 will be referred to as the measured impedance. In examples, the shunt load of the modulator 904 corresponds to a given X/R ratio of the modulator 904. As discussed above, the X/R ratio of the modulator 904 is associated with a corresponding ratio of reactive to active power at the first location 221. Hence, the shunt load of the modulator 904 is associated with a corresponding ratio of reactive to active power at the first location 221.

FIG. 8 also illustrates a plot 806 of the error between the theoretical impedance and the measured impedance, where the plot 806 is a function of the shunt load of the modulator 904. Again, it will be appreciated that the theoretical impedance in this example refers to the magnitude of the theoretical impedance as observed at the first location 221. FIG. 8 illustrates that when the plot 802 of the measured impedance reaches a maximum, the plot 806 of the error between the theoretical impedance and the measured impedance reaches a minimum. Hence, in this example, the first value may be determined to be the maximum value 804 of the measured impedance. Again, because the error is minimised at this point, this method provides an accurate determination of the impedance of the electric power grid as observed at the first location 221.

In some examples, the first value is indicative of a short circuit current of the electric power grid as observed at the first location 221. For example, the short circuit current may refer to the maximum current that flows through a three-phase bolted fault. For example, the short circuit current I_{sc} at the first location 221 may be the nominal voltage Vₙ at the first location 221 divided by the magnitude of the impedance |Z| at the first location 221:

$${I}_{s c} = \frac{{V}_{n}}{\vert Z \vert} = \frac{{V}_{n}}{\sqrt{{R}^{2} + {X}^{2}}} \qquad ( 19 )$$

where in the second step of equation 19, equation 2 has been used to explicitly show the relationship between the short circuit current I_{sc} and the resistance R and reactance X. In some examples, the magnitude of the impedance |Z| in equation may be either the magnitude of the theoretical impedance Z_{T} or the magnitude of the measured impedance Z_{M}, or any determined impedance as described in any of the previous examples.

Accordingly, the short circuit current as observed at the first location 221 may be determined by dividing the determined impedance at the first location 221 by the magnitude of the nominal voltage (whether measured or otherwise known) at the first location 221. As discussed above, the method of FIG. 1 provides an accurate determination of the impedance of the electric power grid as observed at the first location 221. Accordingly, a more accurate short circuit current (e.g. I_{sc} of equation 19) may be determined based on the determined impedance of the electric power grid. This may allow for correct sizing of circuit breakers and other electrical equipment in the system, improving the cost-effectiveness and practicality of the system.

In some examples, the first value is indicative of a short circuit level of the electric power grid as observed at the first location 221. The short circuit level may refer to the apparent power corresponding to a short circuit current I_{sc}. In some examples, the first value may be a short circuit level of the electric power grid as observed at the first location 221. Using the relationship between power, current and voltage in a system, the short circuit level (SCL) at the first location 221 is given by:

$$SCL = {V}_{n} \times {I}_{s c} = \frac{{V}_{n}^{2}}{\vert Z \vert} = \frac{{V}_{n}^{2}}{\sqrt{{R}^{2} + {X}^{2}}} \qquad ( 20 )$$

where the expression for the short circuit current I_{sc}, shown in equation 19, has been used in the second step of equation 20 to express the short circuit level in terms of the magnitude of the impedance |Z|. In the third step of equation 20, equation 2 has been used to explicitly show the relationship between the short circuit level and the resistance R and reactance X. Hence, as the short circuit level (e.g. SCL of equation 20) may be determined based on the short circuit current (e.g. I_{sc} of equation 19), a more accurate determined value of the impedance of the electric power grid allows for a more accurate value of the short circuit level to be determined.

In some examples, the first value may be indicative of a ratio of reactance to resistance (e.g. the X/R ratio) of the electric power grid as observed at the first location 221. Referring to equation 14 and equation 16, the maximum value of the measured impedance (e.g. Z_{M}) corresponds to a particular ratio of reactive to active power, where the particular ratio of reactive to active power is equal to the X/R ratio of the electric power grid as observed at the first location 221. Hence, the X/R ratio of the grid as observed at the first location 221 can be determined by determining the ratio of reactive to active power at the first location 221 corresponding to the maximum measured impedance.

With reference to the examples above, X/R ratio, the impedance, the short circuit level, and the short circuit current are each a function of reactance and resistance. In particular, the X/R ratio is the ratio of reactance to resistance. The complex impedance, as shown in equation 1, combines the resistance and reactance in a complex quantity, describing the opposition to AC current in a system. The magnitude of the complex impedance, as shown in equation 2, takes the absolute value of equation 1, and hence is a function of resistance and reactance. As shown in equation 19 and equation 20 respectively, the short circuit current and the short circuit level each depend on the magnitude of the complex impedance, which itself is a function of reactance and resistance, and hence these values are also functions of reactance and resistance.

In some examples, the method of FIG. 1 may comprise determining a fourth value indicative of the ratio of reactive to active power that corresponds to the determined third value, and determining the first value based on the fourth value. For example, determining the fourth value may comprise determining the ratio of reactive to active power that corresponds to the selected extremum second value. As an example, referring to FIG. 7A, the third value may be the selected maximum second value 704 of the measured impedance. The vertical line shows the value 708 of the X/R ratio of the modulator 904 corresponding to the selected maximum second value 704 of the measured impedance. As discussed above, a fourth value indicative of the ratio of reactive to active power of the electric power grid at the first location 221 may be determined based on the value 708 of the X/R ratio of the modulator 904 corresponding to the selected maximum value 704. In this example, the modulator 904 may be directly connected to the first location 221, as described with reference to FIG. 2A and FIG. 2B. Hence, the X/R ratio of the modulator 904 corresponding to the selected maximum value 704 may be substantially the same as the ratio of reactive to active power of the electric power grid as observed at the first location 221. Accordingly, using the result of equation 14, the X/R ratio of the electric power grid as observed at the first location 221 may be determined based on the fourth value indicative of the ratio of reactive to active power of the electric power grid at the first location 221. As described earlier, in examples where the modulator 904 is not connected at the first location 221, the ratio of reactive to active power of the electric power grid as observed at the first location 221 and hence the X/R ratio of the electric power grid as observed at the first location 221 may be determined based on the X/R ratio of the modulator 904 corresponding to the selected maximum value 704.

In some examples, determining the fourth value may comprise determining, based on the fitted function, the ratio of reactive to active power that corresponds to the extremum value of the fitted function, and determining the fourth value based on the determined ratio of reactive to active power that corresponds to the extremum value of the fitted function. As an example, referring to FIG. 7B, the vertical line shows the value 710 of the X/R ratio of the modulator 904 corresponding to the determined third value of a maximum value of the fitted function. A fourth value indicative of the ratio of reactive to active power of the electric power grid at the first location 221 may be determined based on the value 710 of the X/R ratio of the modulator 904 corresponding to the determined maximum value of the fitted function. Again, using equation 14, this may be equated with the X/R ratio of the electric power grid as observed at the first location 221.

Referring to FIG. 8, the X/R ratio of the electric power grid as observed at the first location 221 may be determined based on the shunt load of the modulator 904. The vertical line shows the value 808 of the shunt load of the modulator 904 corresponding to the maximum of the measured impedance. A fourth value indicative of the ratio of reactive to active power of the electric power grid at the first location 221 may be determined based on the shunt load of the modulator 904. Accordingly, using the result of equation 14, the X/R ratio of the electric power grid as observed at the first location 221 may be determined based on the ratio of reactive to active power of the electric power grid at the first location 221.

In some examples, the method of FIG. 1 may comprise, for each of the plurality of second values, causing one or more power units 219 to perform the respective power change. For example, one or more power units 219 may be connected to the electric power grid and be configured (or configurable) to provide electric power to or consume electric power from the electric power grid 200 with a particular (e.g. configurable) ratio of reactive to active power.

Referring to FIG. 9, there is illustrated a power unit 219 according to an example. In this example, the power unit 219 comprises a power device 906, a modulator 904 and a control unit 902. The power unit 219 is configurable to consume electric power from and/or provide electric power to the electric power grid 200 with a particular ratio of reactive to active power. In this example, the power device 906 is configured to consume electric power from and/or provide electric power to the electric power grid 200. For example, a wind farm, factory, domestic residence, a grid battery, or any other grid asset, may be an example of a power device 906. Indeed, in examples, any device or other grid asset, or combination or subset of such grid assets, that consume electric power from and/or provide electric power to the electric power grid 200, may be a power device 906.

The power unit 219 may comprise a switch (not shown in FIG. 9), where the switch may be used to control power flow to/from the power device 906 by connecting or disconnecting the power unit 219 from the grid 200. For example, when the switch is open, the power unit 219 is disconnected from the grid 200, and the power device 906 neither consumes electric power from and/nor provides electric power to the electric power grid 200. For example, when the switch is closed, the power unit 219 is connected to the grid 200, and the power device 906 either consumes electric power from and/or provides electric power to the electric power grid 200. In examples, the power unit 219 may cause the power change (as described with reference to FIG. 3A) by closing the switch.

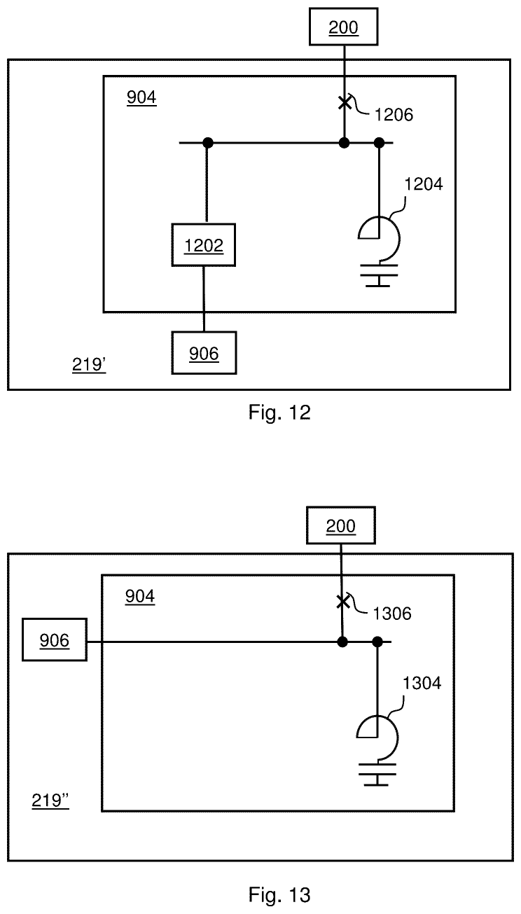

In this example, the modulator 904 is configured to modulate (in other words, modify or change) the electric power flow between the power device 906 and the electric power grid 200 such that the power flow caused by each power change described in step 102 has a respective different ratio of reactive to active power. In this example, the modulator 904 may comprise resistive and/or reactive components such that the modulator 904 has an associated X/R ratio. Details of exemplary modulator 904 arrangements are discussed in more detail with reference to FIG. 12 and FIG. 13. Determining the X/R ratio of the modulator 904 may comprise performing circuit calculations to determine the total reactance of the modulator 904, and the total resistance of the modulator 904, and the ratio of the reactance and the resistance. In examples, adjusting the X/R ratio of the modulator 904 causes a change in the ratio of reactive to active power provided from the power device 906 to the electric power grid 200 or consumed by the power device 906 from the electric power grid 200.

In this example, the control unit 902 is configured to control the modulator 904. The control unit 902 may control the ratio of reactive power to active power with which the power unit 219 consumes power from and/or provides power to the electric power grid 200. For example, the control unit 902 may send a control signal to the modulator 904 to change the X/R ratio of the modulator 904.

In examples, the control unit 902 may be controlled by a central controller 908. The central controller 908 may send control signals to the control unit 902, where the control signals may comprise instructions or operating conditions. In some examples, the central controller 908 may comprise a computing system and/or computing network. In some examples, the central controller 908 may control multiple power units 219 (not shown in FIG. 9). For example, there may be multiple power units 219 at respective multiple different first locations in the grid. The central controller 908 may control the multiple power units 219 each to determine the first value as observed from the respective multiple different first locations. The first values may be transmitted from each control unit to the central controller 908. This may provide for the first value for different first locations in the grid to be determined by the central controller 908, which may give an overview or map of different first values across the grid 200. In some examples, there may be multiple power units 219 at a given first location 221. For example, the multiple power units 219 may be controlled, by the central controller 908 or otherwise, to provide a synchronised power change having a particular ratio of reactive to active power. This may help provide for a relatively large power change to be provided (and hence a relatively small signal to noise ratio for the second values) even where the power rating of individual power units 219 may be relatively small.

In some examples, causing the one or more power units 219 to perform the power change may comprise causing the switch to change from an open configuration to a closed configuration. Referring again to FIG. 3A, the switch may be closed at time t₁. Before this time, the switch is open, the modulator 904 is disconnected from the electric power grid 200, and the power unit 219 does not consume electric power from and/or provide electric power to the electric power grid 200. After the time t₁, the switch is closed, the modulator 904 is connected to the electric power grid 200, and the power unit 219 consumes electric power from and/or provide electric power to the electric power grid 200 with a particular ratio of reactive to active power. For each of the plurality of second values, this power change may be repeated, with the modulator 904 configured to modulate the electric power flow from the power device 906 so as to have a respective different ratio of reactive to active power for each power change.

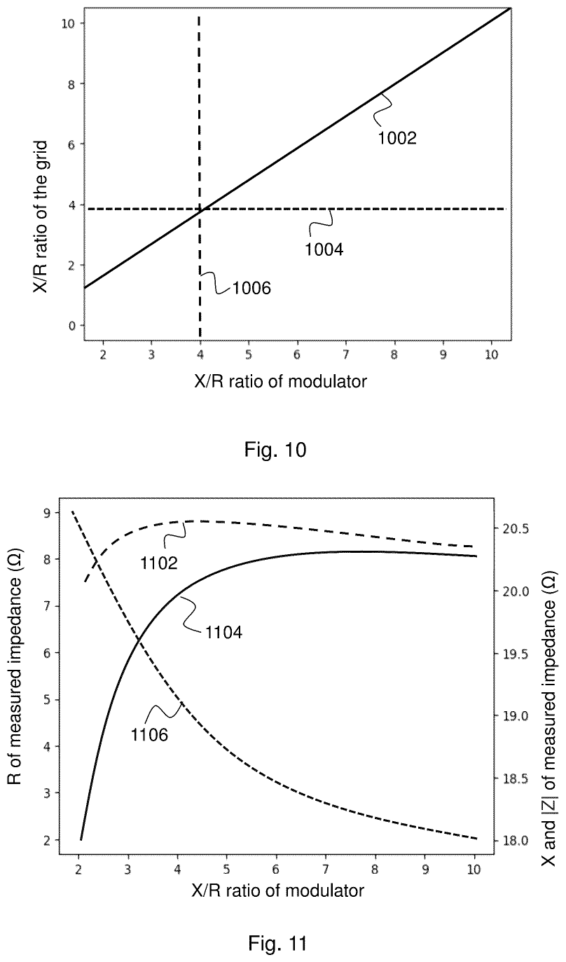

In some examples, a plurality of second values may be obtained for respective different ratios of reactive to active power within a specified range. For example, a plurality of second values may be obtained for ratios of reactive to active power ranging from 2 to 10. The specified range may be determined based on an estimate of the X/R ratio of the electric power grid as observed at the first location 221. Hence, it will be appreciated that the specified range may depend on the particular electric power grid, and the associated properties of the electric power grid. For example, if the X/R ratio is known to be less than or equal to 10 based on estimates from computer models, it may be more efficient to only, or at least initially, obtain second values for ratios of reactive to active power that are less than or equal to 10. However, it will be appreciated that the method of FIG. 1 may be performed for any range of ratios of reactive to active power. In examples, the second values may be obtained at specified intervals as the ratio of reactive to active power is varied within the specified range. For example, the shunt load of the modulator 904 may be adjusted in steps of 0.01 MVAR between obtaining each second value, causing the ratio of reactive to active power at the first location 221 to change in steps. It will be appreciated that the method of FIG. 1 may be performed for any specified interval. For example, the step interval may be decreased as the estimated X/R ratio is approached, which may improve the efficiency and precision of the method. As an example, FIG. 10 illustrates a plot 1002 of the measured X/R ratio of the grid as a function of the X/R ratio of the modulator 904. FIG. 10 also illustrates a plot 1004 of the theoretical X/R ratio of the grid as a function of the X/R ratio of the modulator 904. The plot 1004 of the theoretical X/R ratio of the grid is a horizontal line, showing that the theoretical X/R ratio is a constant with respect to the X/R ratio of the modulator 904. In the example of FIG. 10, the X/R ratio of the modulator 904 was varied from 2 to 10 in steps of 0.01. The plot 1002 of the measured X/R ratio of the grid and the plot 1004 of the theoretical X/R ratio of the grid intersect when the X/R ratio of the modulator 904 matches the theoretical X/R ratio of the grid, as shown by the dashed vertical line 1006. This point of intersection may occur when the measured impedance (or any second value) reaches a maximum value, as described in the examples referring to FIG. 6 to FIG. 8.

In some examples, the power change for each respective ratio of reactive to active power may be repeated. For example, the modulator 904 switch may be opened and closed hundreds of times for a given ratio of reactive to active power. For each power change event, an initial second value may be obtained. To improve the precision of a final second value for the given ratio of reactive to active power, the hundreds of initial second values for that ratio of reactive to active power may be averaged or otherwise analysed to obtain the final second value. Based on this, the final second value provides a more precise measurement of a grid characteristic. For example, the modulator 904 may be switched at around 60 times per minute and switched around 200-400 times to obtain each final second value for a given ratio of reactive to active power. Following obtaining the final second value, the shunt load of the modulator 904 may be adjusted as discussed above, and this process may be repeated for the different ratio of reactive to active power.

In examples where the X/R ratio as observed at a first location 221 of the electric power grid is less than or equal to 10, the method of FIG. 1 provides a determination of the system strength of the electric power grid with particularly improved accuracy, as compared to known methods. In some examples, determining the system strength may comprise determining the short circuit level at the first location 221. At X/R ratios less than or equal to 10, the resistive component becomes non-negligible in grid impedance and system strength calculations. As an example, FIG. 11 illustrates a plot 1102 of the magnitude of the impedance, a plot 1104 of the reactance X, and a plot 1106 of the resistance R, as observed at a first location 221 in an electric power grid, each as a function of the X/R ratio of the modulator 904. FIG. 11 illustrates that as the X/R ratio increases, approaching 10, the plot 1104 of the reactance X and the plot 1102 of the magnitude of the impedance approach one another. Accordingly, the plot 1106 of the resistance R approaches zero. Hence, for X/R values much greater than 10, the reactance X may be a reasonable approximation for the magnitude of the impedance. However, FIG. 11 also illustrates that as the X/R ratio tends towards values less than 10, the plot 1106 of the resistance R increases. Additionally, the difference between the plot 1104 of the reactance X and the plot 1102 of the magnitude of the impedance increases. Hence, for X/R values less than or equal to 10, the contribution from the resistance R is significant. Accordingly, both the reactance X and the resistance R may be useful in determining an accurate impedance. Hence, by determining an accurate value of the X/R ratio of the electric power grid as observed at a first location 221 of the electric power grid, the accuracy of the determined values of impedance and system strength may be improved.

In some examples, the method of FIG. 1 may comprise determining, based on the determined first value, one or more settings for a voltage control system for controlling voltage at the first location 221 of the electric power grid by providing to the electric power grid or consuming from the electric power grid reactive and/or active power. In this example, determining a more accurate X/R ratio of the electric power grid as observed at the first location 221 allows for an improved voltage control system. Traditionally, voltage control systems may provide and/or consume only reactive power to the electric power grid, to compensate for a drop in voltage. In these examples, typical voltage control systems may provide and/or consume only reactive power to the electric power grid using capacitive and/or reactive loads. However, in low X/R grids where the drop in voltage may be caused by a drop in active power, more effective voltage compensation may arise from providing and/or consuming both reactive and active power to/from the electric power grid. Additionally, by matching the ratio of reactive to active power provided and/or consumed by the voltage control system to the X/R ratio of the grid, a more effective and/or efficient voltage compensation may be provided. Hence, by determining an accurate value of the X/R ratio of the grid, the effectiveness and/or efficiency of the voltage control system is improved. In some examples, the voltage control system may comprise inverter-based resources, such as an inverter. Improving the effectiveness of the voltage compensation may improve the stability of inverter-based resources in the electric power grid.

In some examples, the voltage control system may comprise one or more power units 219. Referring to step 102, each power change causing an electric power flow in the electric power grid at the first location 221 with a respective different ratio of reactive to active power may be performed by the one or more power units 219. In some examples, the one or more power units 219 of the voltage control system may perform the power change of step 102. Hence, the method of FIG. 1 may be performed for the first location 221 of the voltage control system, based on power changes performed by the voltage control system. This may allow accurate determination of the X/R ratio or the impedance at the location of the voltage control system. Hence, the settings of the voltage control system are determined based on the X/R ratio or the impedance determined at the location of the voltage control system. This may provide for efficient and/or self-contained operation of the voltage control system.

In some examples, the one or more power units 219 may comprise a variable resistive load in parallel with a fixed reactor. In some examples, for each of the plurality of second values, causing the one or more power units 219 to perform the respective power change comprises causing the variable resistive load to be adjusted so that the one or more power units 219 provide electric power to or consume electric power from the electric power grid at the first location 221 with a respective different ratio of reactive to active power. In some examples, the modulator 904 of the power unit 219 may comprise the variable resistive load in parallel with the fixed reactor. In examples where the variable resistive load is in parallel with the fixed reactor, the variable resistive load may be referred to as the shunt load.

Known modulators may only comprise capacitive and/or reactive loads, hence only providing and/or consuming reactive power to the electric power grid. FIG. 12 and FIG. 13, described in more detail below, illustrate modulator 904 arrangements that are configured to provide and/or consume both reactive and active power to the electric power grid.

Referring to FIG. 12, there is illustrated an example power unit 219′ comprising a modulator 904 and a power device 906. The modulator 904 comprises a variable resistive load 1202, a reactor 1204, and a switch 1206. In this example, the variable resistive load 1202 and the reactor 1204 are arranged in a parallel configuration. The modulator 904 is connected to the power device 906, such that the modulator 904 is configured to modulate the electric power flow from the power device 906 to the electric power grid 200 or from the electric power grid to the power device 906. The power unit 219′ may also comprise a control unit (not shown in FIG. 12), for example, as described above with reference to FIG. 9. The variable resistive load 1202 may change the active power provided to the grid 200 and/or consumed from the grid 200. The variable resistive load 1202 may comprise a variable resistor for adjusting the value of the load 1202. For example, the variable resistor may be arranged in series with the power device 906, where the power device 906 may provide and/or consume active power. For example, the power device 906 may as per any of the examples described above with reference to FIG. 9. For example, adjusting the resistance of the variable resistor may change the active power provided to the grid 200 and/or consumed by power grid 200 from the power device 906. The variable resistive load 1202 may have high granularity, allowing the variable resistive load 1202 to be adjusted in small increments, allowing for more precise control. Other examples are possible.

In examples, the reactor 1204 may provide to the grid 200 and/or consume from the grid 200 a fixed value of reactive power. For example, the reactor 1204 may be a shunt reactor for providing reactive power to the grid and/or consuming reactive power from the grid 200. The reactor 1204 may be an inductive load, such as an inductor or a coil. The reactor 1204 may have a fixed quality-factor (QF) to provide to the grid 200 and/or consume to the grid 200 a fixed value of reactive power. Additionally, the QF value may relatively low, such as a value below 10. This may improve the damping of oscillations and/or transients caused by actuation of the switch 1206. The reactor 1204 may comprise a fixed series resistor, where the fixed series resistor provides a low QF value. Additionally, fixed series resistor may be configured to avoid unwanted fluctuations or instabilities caused by high frequency switching of the modulator 904.

By adjusting the active power provided to the grid 200 and/or consumed by the grid 200 using the variable resistive load 1202, while maintaining a fixed value of reactive power provided to the grid 200 and/or consumed by the grid 200 using the reactor 1204, the ratio of reactive to active power from the power device 906 to the electric power grid 200 may be adjusted. Hence, the ratio of reactive to active power of a power flow at the first location 221 caused by a power change by the power unit 219′ may be adjusted. The example modulator 904 of FIG. 12 allows the adjustment of the ratio of reactive to active power in a simple and inexpensive manner. Additionally, the variable resistive load 1202 is configured to be in parallel with the fixed reactor 1204, causing the components to be separated. This prevents heat from the variable resistive load 1202 causing damage to the fixed reactor 1204. Accordingly, this arrangement improves the efficiency of the modulator 904.

As discussed earlier, the power unit 219 may also comprise a switch. In some examples, this switch may be the switch 1206 of the modulator 904. The switch 1206 may be a solid-state switch and may be used to control power flow to/from a power unit 219 by connecting or disconnecting the modulator 904 from the grid 200.

In some examples, the control unit 902 may send a control signal to the modulator 904 to adjust the variable resistive load 1202. In these examples, the modulator 904 may determine the adjustment of the variable resistive load 1202 based on the control signal. The control signal sent from the control unit 902 to the modulator 904 may be determined by the central controller 908.

In some examples, the one or more power units 219 may comprise a reactor with a variable quality factor. In some examples, for each of the plurality of second values, causing the one or more power units 219 to perform the respective power change comprises causing the variable quality factor to be adjusted so that the one or more power units 219 provide electric power to and/or consume electric power from the electric power grid at the first location 221 with a respective different ratio of reactive to active power. In some examples, the modulator 904 comprising the power unit 219 may comprise the reactor with the variable quality factor.

Referring to FIG. 13, there is illustrated an example power unit 219″ comprising a modulator 904 and a power device 906. The modulator 904 comprises a reactor 1304 with a variable quality factor, and a switch 1306. The modulator 904 is connected to the power device 906, such that the modulator 904 is configured to modulate the electric power flow from the power device 906 to the electric power grid 200 or from the electric power grid to the power device 906. The connection between the control unit 902 and the modulator 904 is not shown in FIG. 12. Varying the quality factor of the reactor 1304 may change the ratio of reactive to active power provided to the grid and/or consumed to the grid 200 by the power unit 219″. In some examples, the reactor 1304 may comprise a reactor bank and a variable resistor, where the reactor bank and the variable resistor are arranged in series. The reactor bank may comprise one or more inductive loads. Examples of such inductive loads include an inductor or a coil. The resistance of the variable resistor may be adjusted to adjust the quality factor of the reactor. For example, increasing the resistance of the variable resistor causes more active power to be consumed by the reactor, and hence the quality factor of the reactor decreases. Accordingly, adjusting the resistance of the variable resistor also adjusts the active power provided to the power grid 200 and/or consumed by the power grid 200 by the power device 906. Hence, by adjusting the resistance of the variable resistor, the ratio of reactive to active power provided to the power grid 200 and/or consumed to the power grid 200 by the power device 906 may be adjusted. The example modulator 904 arrangement of FIG. 13 allows the ratio of reactive to active power to be adjusted efficiently, while reducing the number of components used in the modulator 904.

As in FIG. 12, the switch 1306 may be a solid-state switch and may be used to control power flow to the power unit 219 and/or from a power unit 219 by connecting or disconnecting the modulator 904 from the grid 200.

In some examples, the control unit 902 may send a control signal to the modulator 904 to adjust the quality factor of the reactor 1304. In these examples, the modulator 904 may determine the adjustment of the resistance of the variable resistor based on the control signal. The control signal sent from the control unit 902 to the modulator 904 may be determined by the central controller 908.

In examples, the one or more power units 219 may comprise an inverter. In some examples, for each of the plurality of second values, causing the one or more power units 219 to perform the respective power change comprises causing the inverter to provide electric power to and/or consume electric power from the electric power grid at the first location 221 with a respective different ratio of reactive to active power. In some examples, the modulator 904 comprising the power unit 219 may comprise the inverter. In some examples, the inverter may adjust the amplitude of the voltage and/or the current of the electricity flowing through the inverter, and the phase angle between the voltage and the current. In doing so, the inverter may adjust the ratio of reactive to active power provided to and/or consumed by the power grid 200 by the power device 906. For example, the inverter may adjust the active power provided to and/or consumed by the power grid 200 by the power device 906. The use of an inverter provides precise control of the ratio of reactive to active power.

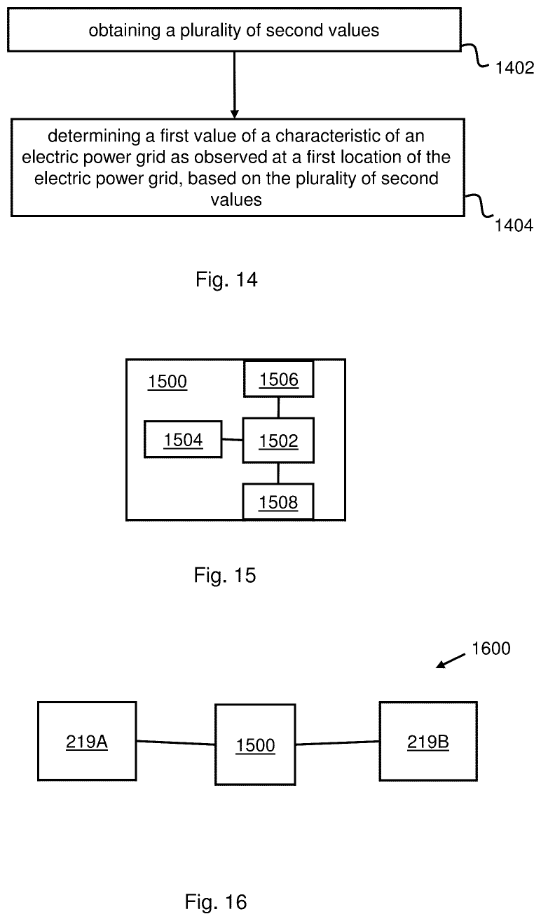

Referring to FIG. 14, there is illustrated a method of determining a first value of a characteristic of an electric power grid 200 as observed at a first location of the electric power grid 200, according to an example. In broad overview, the method comprises:
in step 1402, obtaining a plurality of second values, each second value being indicative of a relationship between a difference in measured voltage of the electric power grid at the first location before and after a respective power change and a difference in measured current of the electric power grid at the first location before and after the respective power change, each power change causing an electric power flow in the electric power grid at the first location with a respective different ratio of reactive to active power; and
in step 1404, determining the first value based on the plurality of second values.

Referring to step 1402, the method may comprise the features of step 102 according to any of the examples described above with reference to FIGS. 1 to 13. Additionally, referring to step 1404, the method may comprise the features of step 104, or of step 104 and step 106, according to any of the examples described above with reference to FIGS. 1 to 13. The method of FIG. 14 may allow for a value of a characteristic of the electric power grid 200 to be determined more accurately and/or on demand.

Referring to FIG. 15, there is illustrated an apparatus 1500 configured to perform the method of either FIG. 1 or FIG. 14, according to an example. The apparatus 1500 comprises a processor 1502, a memory 1504, an input interface 1506, and an output interface 1508. In examples, the apparatus 1500 may be configured to perform the method of any of the examples described above with reference to FIG. 1 to FIG. 14. The memory 1504 may store a computer program which, when executed by the processor 1502 causes the processor 1502 to perform the method according to any of the examples described above with reference to FIG. 1 to FIG. 14. In examples, the input interface 1506 may receive the plurality of second values. In examples, the input interface 1506 may receive, for example, from a measurement device 220, measured voltage of the electric power grid at the first location 221 before and after a respective power change and a measured current of the electric power grid at the first location 221 before and after the respective power change, for example as described above. In examples, for each of the plurality of second values, the input interface 1506 may receive the second value along with the respective ratio of reactive to active power that was used to obtain the second value. In examples, the output interface 1508 may be connected to a computer network such as the internet. In examples, the processor 1502 may output, via the output interface 1508, one or more sets of data, as per any of the examples described above, to a computing system. In examples, the processor 1502 may output the determined first value via the output interface 1508. In examples, the output interface 1508 may be connected to a computer display such as a computer monitor (not shown in FIG. 15). In examples, the processor 1508 may be configured, via the output interface 1508, to display the determined first value of the electric power grid characteristic on the computer display. In examples, the output interface 1508 may be connected to a further storage (not shown in FIG. 15) and the processor 1502 may output the determined first value of the electric power grid characteristic to the further storage via the output interface 1508.

Referring to FIG. 16, there is illustrated a system 1600 comprising the apparatus 1500 of FIG. 15, a first power unit 219A, and a second power unit 219B, according to an example. The power units 219A, 219B may be the same as or similar to the power unit 219 according to any one of the examples described above with reference to FIGS. 1 to 14. Referring to FIG. 16, the apparatus 1500 may control and/or communicate with the power units 219A, 219B. For example, the power units 219A, 219B may be in communication with the apparatus 1500 over a computing network, such as the Internet. For example, the apparatus 1500 may be configured to control the power units 219A, 219B to perform the power changes as per any of the examples described above. For example, in this case the apparatus 1500 may act as the central controller 908 according to any of the examples described above. As another example, the power units 219A, 219B may send data regarding power change(s) that the power units 219A, 219B have performed, to the apparatus 1500. For example, the power units 219A, 219B may send data indicative of a time, magnitude, and/or ratio of reactive to active power, of a power change performed by the power unit 219A and/or a location and/or identifier of the power unit 219A. The apparatus 1500 may then, for example, correlate the power changes to measured voltage and current changes, e.g. to determine the ratio of reactive to active power associated with a particular measured voltage and current change. In some examples, the system 1600 may also comprise one or more measurement devices 220 (not shown in FIG. 16) and a network. Measurement devices (not shown in FIG. 16) may be in communication with the apparatus 1500 over a computing network, such as the Internet. Specifically, the measurement devices may be configured to send measurement data to the computing system over the network for example as per any one of the examples described above with reference to FIGS. 1 to 14. It will be appreciated that the system 1600 may comprise the apparatus 1500 and one or more power units 219, not necessarily only two power units 219A, 219B as shown in FIG. 16.

In other examples, not shown in FIG. 16, a power unit 219 may comprise the apparatus 1500, such that the apparatus 1500 may be integrated within or otherwise part of the power unit 219. In examples, the apparatus 1500 may comprise a power unit 219. In examples, one or more of the power units 219A, 219B may be configured to perform the method according to any one of the examples described above with reference to FIG. 1 or FIG. 14.

In some of the above examples, a third value indicative of an extremum of the relationship (e.g. measured impedance) is determined. For example, as per FIG. 7A, a maximum second value 704 is selected and taken as the third value. As another example, as per FIG. 7B, a maximum value 712 of the fitted function 706 is taken as the third value. In these illustrated examples, the extremum (e.g. maximum) corresponds to an inflection point in the relationship. That is, the third value is indicative of an inflection point of the relationship. Determining a third value indicative of the inflection point of the relationship may, for example, allow for a particularly accurate first value to be determined. However, it will be appreciated that this need not necessarily be the case, and that in other examples the extremum need not necessarily correspond to an inflection point of the relationship. That is, the third value need not necessarily be indicative of an inflection point of the relationship. For example, if the plurality of obtained second values includes two second values (e.g. of measured impedance), then determining a third value indicative of an extremum of the relationship may comprise determining the higher of these two second values. This determined highest second value need not necessarily indicate the highest possible second value (e.g. an inflection point representing the global maximum amongst all possible second values), but nonetheless will provide for a more accurate determination of the first value, for example as compared to if the lower second value were used to determine the first value instead. Accordingly, it will be appreciated that, in examples, any two or more second values indicative of a relationship (e.g. measured impedance) may be obtained, and a third value indicative of an extremum of the relationship (e.g. the highest among the any two or more second values) may be determined.

In some of the above examples, it is described that a power unit 219 may be configurable to provide or consume power with a configurable ratio of reactive to active power. However, it will be appreciated that this need not necessarily be the case, and that in other examples non-configurable, or indeed any, power units 219 may be used. For example, the one or more power units 219 may comprise a plurality of power units 219, each configured to provide or consume power with a respective different ratio of reactive to active power. In such examples, each power change may be provided by a respective different one of the plurality of power units 219. More generally, it will be appreciated that the power change need not necessarily be provided by a power unit 219 as per the examples described above at all, and that any power change (produced by any means) which causes an electric power flow in the electric power grid 200 at the first location 221 with a particular ratio of reactive to active power may be used.

The above examples are to be understood as illustrative examples of the invention. Further examples of the invention are envisaged. It is to be understood that any feature described in relation to any one example may be used alone, or in combination with other features described, and may also be used in combination with one or more features of any other of the examples, or any combination of any other of the examples. Furthermore, equivalents and modifications not described above may also be employed without departing from the scope of the invention, which is defined in the accompanying claims.

1. A method of determining a first value of a characteristic of an electric power grid as observed at a first location of the electric power grid, the method comprising:
obtaining a plurality of second values, each second value being indicative of a relationship between a difference in measured voltage of the electric power grid at the first location before and after a respective power change and a difference in measured current of the electric power grid at the first location before and after the respective power change, each power change causing an electric power flow in the electric power grid at the first location with a respective different ratio of reactive to active power;
determining, based on the plurality of second values, a third value indicative of an extremum of the relationship; and
determining the first value based on the third value.

2. The method according to claim 1, wherein each second value is indicative of a ratio of the difference in measured voltage of the electric power grid at the first location before and after the respective power change to the difference in measured current of the electric power grid at the first location before and after the respective power change.

3. The method according to claim 2, wherein the third value is indicative of a maximum of the ratio.

4. The method according to claim 2, wherein each second value is indicative of a measured impedance of the electric power grid at the first location.

5. The method according to claim 1, wherein, for each second value, the measured voltage comprises a magnitude of the voltage before and after the respective power change, and the measured current comprises a magnitude of the current, and a phase of the current relative to the voltage, before and after the respective power change.

6. The method according to claim 1, wherein determining the third value comprises:
selecting an extremum second value from among the plurality of second values; and
determining the third value based on the selected extremum second value.

7. The method according to claim 1, wherein determining the third value comprises:
fitting a function to the plurality of second values, the function being a function of the ratio of reactive to active power;
determining an extremum value of the fitted function; and
determining the third value based on the determined extremum value of the fitted function.

8. The method according to claim 1, wherein the method comprises, for each of the plurality of second values:
measuring the respective ratio of reactive to active power of the electric power flow in the electric power grid at the first location caused by the respective power change.

9. The method according to claim 1, wherein, for each of the plurality of second values, the respective power change provides electric power to or consumes electric power from the electric power grid at the first location with the respective different ratio of reactive to active power.

10. The method according to claim 1, wherein the first value is indicative of a function of reactance and resistance of the electric power grid as observed at the first location.

11. The method according to claim 1, wherein the first value is indicative of an impedance, a short circuit current, or a short circuit level of the electric power grid as observed at the first location.

12. The method according to claim 1, wherein the first value is indicative of a ratio of reactance to resistance of the electric power grid as observed at the first location.

13. The method according to claim 1, wherein the method comprises, for each of the plurality of second values:
causing one or more power units to perform the respective power change.

14. The method according to claim 1, wherein the method comprises, for each of the second values:
obtaining voltage values indicative of the measured voltage of the electric power grid at the first location before and after the respective power change; and
obtaining current values indicative of the measured current of the electric power grid at the first location before and after the respective power change; and
determining the second value based on the obtained voltage values and the obtained current values.

15. The method according to claim 1, wherein the method comprises:
determining, based on the determined first value, one or more settings for a voltage control system for controlling voltage at the first location of the electric power grid by providing to the electric power grid or consuming from the electric power grid reactive and/or active power.

16. The method according to claim 15, wherein the method comprises, for each of the plurality of second values:
causing one or more power units to perform the respective power change; and
wherein the voltage control system comprises the one or more power units.

17. The method according to claim 1, wherein the ratio of reactance to resistance of the electric power grid as observed at a first location of the electric power grid is less than or equal to 10.

18. A method of determining a first value of a characteristic of an electric power grid as observed at a first location of the electric power grid, the method comprising:
obtaining a plurality of second values, each second value being indicative of a relationship between a difference in measured voltage of the electric power grid at the first location before and after a respective power change and a difference in measured current of the electric power grid at the first location before and after the respective power change, each power change causing an electric power flow in the electric power grid at the first location with a respective different ratio of reactive to active power;
determining the first value based on the plurality of second values.

19. Apparatus configured to perform a method of determining a first value of a characteristic of an electric power grid as observed at a first location of the electric power grid, the method comprising:
obtaining a plurality of second values, each second value being indicative of a relationship between a difference in measured voltage of the electric power grid at the first location before and after a respective power change and a difference in measured current of the electric power grid at the first location before and after the respective power change, each power change causing an electric power flow in the electric power grid at the first location with a respective different ratio of reactive to active power; and
determining the first value based on the plurality of second values.

20. A system comprising an apparatus and one or more power units, the apparatus being configured to perform a method of determining a first value of a characteristic of an electric power grid as observed at a first location of the electric power grid, the method comprising:
obtaining, by the apparatus, a plurality of second values, each second value being indicative of a relationship between a difference in measured voltage of the electric power grid at the first location before and after a respective power change and a difference in measured current of the electric power grid at the first location before and after the respective power change, each power change causing an electric power flow in the electric power grid at the first location with a respective different ratio of reactive to active power; and
determining, by the apparatus, the first value based on the plurality of second values,
wherein the method comprises, for each of the plurality of second values:
causing the one or more power units to perform the respective power change.

21. A computer program comprising instructions which, when executed by a computing system, causes the computing system to perform a method of determining a first value of a characteristic of an electric power grid as observed at a first location of the electric power grid, the method comprising:
obtaining a plurality of second values, each second value being indicative of a relationship between a difference in measured voltage of the electric power grid at the first location before and after a respective power change and a difference in measured current of the electric power grid at the first location before and after the respective power change, each power change causing an electric power flow in the electric power grid at the first location with a respective different ratio of reactive to active power; and
determining the first value based on the plurality of second values.
